(19) United States
(12) Patent Application Publication
(10) Pub. No.: US 2008/0128728 A1
(43) Pub. Date: Jun. 5, 2008

(54) Polarized light-emitting devices and methods

(75) Inventors: Nikolay I. Nemchuk, North Andover, MA (US); Alexander L. Pokrovskiy, Burlington, MA (US); Michael Lim, Cambridge, MA (US); Alexei A. Erchak, Cambridge, MA (US)

Correspondence Address: WOLF GREENFIELD & SACKS, P.C., 600 ATLANTIC AVENUE, BOSTON, MA, 02210-2206, US

(73) Assignee: Luminus Devices, Inc., Woburn, MA (US)

(21) Appl. No.: 11/804,209

(22) Filed: May 17, 2007

Related U.S. Application Data
(63) Continuation-in-part of application No. 11/209,905, filed on Aug. 23, 2005.
(60) Provisional application No. 60/608,835, filed on Sep. 10, 2004.
(60) Provisional application No. 60/881,823, filed on Jan. 22, 2007.

(51) Int. Cl. H01L 33/00

(52) U.S. Cl. 257/98; 257/E33.068

(57) ABSTRACT

Light-emitting devices and/or systems are described. In one embodiment, a light-emitting device comprises a light-emitting material stack including a light-generating region and a light emission surface, and a polarizer configured to receive at least some light emitted from the light emission surface of the light-emitting material stack, wherein the polarizer comprises first reflective regions at a first height and second reflective regions separated from the first metal regions and at a second height different from the first height.

### RELATED APPLICATIONS

This application claims priority under 35 U.S.C. § 119(e) to U.S. Provisional Application Ser. No. 60/881,823 entitled “Light recycling devices and systems and method of manufacturing the same,” and filed on Jan. 22, 2007. This application also claims priority under 35 U.S.C. §120 to, and is a continuation-in-part of U.S. application Ser. No. 11/209,905 (published as U.S. Patent Publication No. 20060043400) entitled “Polarized light emitting device,” and filed Aug. 23, 2005, which claims priority under 35 U.S.C. § 119(e) to U.S. Provisional Application Ser. No. 60/608,835 filed on Sep. 10, 2004. All of the above-noted applications are herein incorporated by reference in their entirety.

### FIELD

The present embodiments are drawn generally towards light-emitting devices and/or systems, and more specifically to light-emitting devices (e.g., light-emitting diodes) and/or systems that can recycle light or facilitate the emission of light with desired properties.

### BACKGROUND

A light-emitting diode (LED) can provide light in a more efficient manner than an incandescent and/or a fluorescent light source. The relatively high power efficiency associated with LEDs has created an interest in using LEDs to displace conventional light sources in a variety of lighting applications. For example, in some instances LEDs are being used as traffic lights and to illuminate cell phone keypads and displays.

Typically, an LED is formed of multiple layers, with at least some of the layers being formed of different materials. In general, the materials and thicknesses selected for the layers influence the wavelength(s) of light emitted by the LED. In addition, the chemical composition of the layers can be selected to promote isolation of injected electrical charge carriers into regions (e.g., quantum wells) for relatively efficient conversion to light. Generally, the layers on one side of the junction where a quantum well is grown are doped with donor atoms that result in high electron concentration (such layers are commonly referred to as n-type layers), and the layers on the opposite side are doped with acceptor atoms that result in a relatively high hole concentration (such layers are commonly referred to as p-type layers).

LEDs also generally include contact structures (also referred to as electrical contact structures or electrodes), which are conductive features of the device that may be electrically connected to a power source. The power source can provide electrical current to the device via the contact structures, e.g., the contact structures can deliver current along the lengths of structures to the surface of the device within which light may be generated.

In some systems or sub-systems that incorporate light-emitting devices (e.g., LEDs or laser diodes), light output from the light-emitting device may not possess optical characteristics that are desired for the system or sub-systems. Examples of optical characteristics can include polarization state, propagation direction, and/or wavelength. Examples of systems or sub-systems utilizing light from light-emitting devices can include optical sub-systems, such as sub-systems of a display system, for example a micro-display projection system, or a liquid crystal display (LCD) system. Examples of micro-display projection systems include micro-mirror display systems and liquid crystal on silicon systems (LCOS). Currently, light from a light-emitting device can be filtered so that the resulting light possess the desired optical characteristic(s) prior to providing that light to the system or sub-system, however, such filtering may waste a significant amount of the light generated by the light-emitting device.

### SUMMARY

Light-emitting devices, and related components, systems, and methods associated therewith are provided.

In one aspect, a light-emitting device comprises a light-emitting material stack including a light-generating region and a light emission surface, and a polarizer configured to receive at least some light emitted from the light emission surface of the light-emitting material stack, wherein the polarizer comprises first reflective regions at a first height and second reflective regions separated from the first metal regions and at a second height different from the first height.

In another aspect, a light-emitting device comprises a light-emitting material stack including a light-generating region and a light emission surface, a material region disposed over the light emission surface of the light-emitting material stack and comprising surface features having tapered cross-sections, and a polarizer configured to receive at least some light emitted from the light emission surface of the light-emitting material stack, wherein the polarizer comprises reflective regions disposed over at least some of the surface features of the material region, wherein the reflective regions of two adjacent surface features are isolated from each other.

In another aspect, a light-emitting device comprises an active region that generates light, and a polarizer disposed relative to the active region such that a majority of the generated light has a first polarization.

In another aspect, a method of making a light-emitting device is provided. The method comprises providing a light-emitting material stack including a light-generating region and a light emission surface, and providing a polarizer configured to receive at least some light emitted from the light emission surface of the light-emitting material stack, wherein the polarizer comprises first reflective regions at a first height and second reflective regions separated from the first metal regions and at a second height different from the first height.

Other aspects, embodiments and features of the invention will become apparent from the following detailed description of the invention when considered in conjunction with the accompanying figures. The accompanying figures are schematic and are not intended to be drawn to scale. Each identical or substantially similar component that is illustrated in various figures is represented by a single numeral or notation.

For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF FIGURES

FIG. 1 is a schematic drawing of a cross-section view of a light-emitting system in accordance with one embodiment;

FIG. 2 is a schematic drawing of a cross-section view of a light-emitting system in accordance with one embodiment;

FIG. 3 is a schematic drawing of a cross-section view of a light-emitting system in accordance with one embodiment;

FIG. 4 is a schematic drawing of a cross-section view of a light-emitting system in accordance with one embodiment;

FIG. 5 is a schematic drawing of a light-emitting die in accordance with one embodiment;

FIG. 6 is a schematic drawing of a cross-section view of a light-emitting system in accordance with one embodiment;

FIG. 7 is a schematic drawing of a cross-section view of a light-emitting system in accordance with one embodiment;

FIG. 8 is a schematic drawing of a cross-section view of a polarization recycling light-emitting system in accordance with one embodiment;

FIG. 9 is a schematic drawing of a cross-section view of a polarization recycling light-emitting device in accordance with one embodiment;

FIG. 10a is a schematic drawing of a polarization recycling light-emitting device in accordance with one embodiment;

FIGS. 10b-c are schematic drawings of cross-section views of structures formed by deposition in accordance with one embodiment;

FIG. 11a is a schematic drawing of a polarization recycling light-emitting device in accordance with one embodiment;

FIG. 11b is a schematic drawing of a cross-section view of a structure formed by deposition in accordance with one embodiment;

FIGS. 12a-c are schematic drawings of cross-section views of multi-level wire-grid polarizer structures in accordance with one embodiment;

FIG. 13 is a schematic drawing of a cross-section view of a polarization recycling light-emitting device in accordance with one embodiment;

FIG. 14 is a schematic drawing of a cross-section view of a polarization recycling light-emitting device in accordance with one embodiment;

FIG. 15 is a schematic drawing of a cross-section view of a light-emitting device including one or more wire-grid polarizers in accordance with one embodiment;

FIGS. 16a-b are schematic drawings of cross-section views of light-emitting devices including wire-grid polarizer structures in accordance with one embodiment;

FIG. 17 are calculated results for a polarization recycling light-emitting device in accordance with one embodiment;

FIG. 18 are calculated results for a polarization recycling light-emitting device in accordance with one embodiment;

FIG. 19 are calculated results for a polarization recycling light-emitting device in accordance with one embodiment;

FIG. 20 is a schematic drawing of a cross-section view of a polarization recycling light-emitting assembly in accordance with one embodiment;

FIG. 21 is a top view of the assembly of FIG. 20 in accordance with one embodiment;

FIG. 22 is a schematic drawing of a polarization recycling liquid crystal display (LCD) system in accordance with one embodiment;

FIG. 23a is a schematic drawing of a cross-section view of a propagation direction recycling light-emitting system in accordance with one embodiment;

FIG. 23b is a schematic drawing of a top view of a propagation direction recycling light-emitting system in accordance with one embodiment;

FIG. 24a is a schematic drawing of a top view of a light-emitting device having multiple reflective regions disposed on top of an emission surface in accordance with one embodiment;

FIG. 24b is a schematic drawing of a cross-section view of a light-emitting device having a reflective region disposed on top of an emission surface in accordance with one embodiment;

FIG. 25 is a schematic drawing of a cross-section view of a wavelength recycling light-emitting system in accordance with one embodiment;

FIG. 26 is a schematic drawing of a cross-section view of a light-emitting system in accordance with one embodiment; and

FIG. 27 is a schematic drawing of a cross-section view of a light-emitting system in accordance with one embodiment.

### DETAILED DESCRIPTION

In some embodiments presented herein, at least some light not having a desired optical characteristic(s) (e.g., polarization, propagation direction, and/or wavelength) is recycled and transformed into light having the desired optical characteristic(s). In some embodiments, light recycling is performed, in part or in whole, by structures of a light-emitting device and/or a light-emitting system or sub-system. Light recycling may be performed by structures of a light-emitting die and/or a package of the light-emitting die. Light recycling can enhance the amount of light that has the desired optical characteristic. Light recycling can thus improve the power efficiency of optical systems.

One or more embodiments presented herein include a light-emitting device and/or system which can recycle light generated by a light-generating region. The recycling of light may enhance outputted light intensity (emitted by the device and/or system) having a desired optical property, also referred to herein as a characteristic state (e.g., polarization, propagation direction, and/or wavelength).

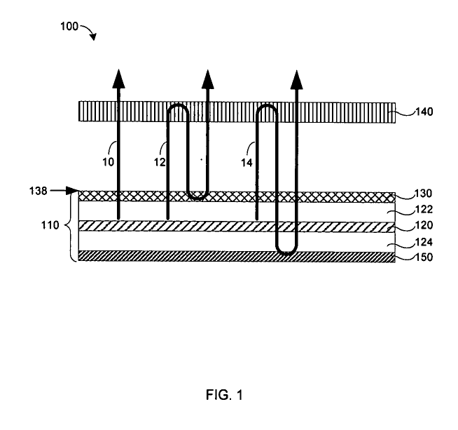

FIG. 1 illustrates a light-emitting system 100 including a light-generating region 120 (e.g., active region) of a light-emitting device 110 in accordance with one embodiment. In some embodiments, all the elements of light-emitting system 100 can be integrated as part of a light-emitting device or a packaged light-emitting device. However, a light-emitting system may include components external to a light-emitting device. Such components may include optical components external to the light-emitting device, such as lens, prisms, arrays of prisms, mirrors, polarizers, waveguides, and/or optical fibers that are not integrated with the light-emitting device.

Light-emitting device 110 (e.g., a light-emitting die) may be a semiconductor light-emitting device. Light generated by light-generating region 120 of the light-emitting device 110 may be emitted via an emission surface 138 of the light-emitting device. In some embodiments, the light emitting device 110 may include a semiconductor light-emitting material stack that may include an active region that generates light and a surface of the semiconductor material stack that may serve as light emission surface (e.g., through which some, a majority, or substantially all of the emitted light is extracted). As used herein, the emission surface of the light-emitting device may be partially or totally in contact with another material (e.g., dielectric, encapsulant material, and/or metal) and/or exposed to a gas or vacuum.

Light-emitting device 110 may include a reflective layer 150 (e.g., one or more metal layers, a dielectric and/or a semiconductor mirror stack, such as a Bragg reflector) on a backside of the light-emitting die. Light-emitting device 110 may include an n-type (p-type) layer 122 and a p-type (n-type) layer 124. The light-generating region 120 may be an active region disposed between layer 122 and 124. Although not shown, it will be appreciated by those of ordinary skill in the art, that light-emitting device 110 can include a top electrical contact (e.g., n contacts or p-contacts) to provide for electrical injection, as discussed further below. A backside electrical contact may be achieved via an electrical contact to reflective layer 150 which may be electrically conductive (e.g., may include one or more metal layers).

Light-emitting system 100 can include a feedback element 140 that can return (e.g., reflect or direct towards a manipulation region 130, as described further below) at least some light having a first characteristic state and can output (e.g., transmit) at least some light having a second characteristic state. At least part of feedback element 140 may be part of light-emitting device 110 (e.g., part of a light-emitting die). For example, feedback element 140 can include a layer of light-emitting device 110. Alternatively, or additionally, feedback element 140 may include at least a portion of a package of light-emitting device 110. For example, a window (e.g., a glass layer) of a package of light-emitting device 110, through which emitted light may be transmitted, can include a portion or all of feedback element 140. In some embodiments, a portion of a package of light-emitting device 110 may form a feedback element that includes a cavity having a partially or totally reflective interior and one or more apertures, as described further below.

The characteristic of the light upon which the operation of the feedback element 140 depends may include polarization, propagation direction, and/or wavelength. The polarization state may include linear, circular and/or elliptical polarization states. The wavelength state may include one or more wavelength ranges and/or one or more wavelengths (e.g., wavelength ranges having narrow bandwidths). The propagation direction state may include the light propagation direction (e.g., a unit normal vector along the direction of light propagation) or components of the light propagation direction, for example, a tangentential component and/or a perpendicular component of the light propagation direction. The tangentential component may be a component of the light propagation direction parallel to the light-generating region (e.g., active layer) and/or the emission surface of the light-emitting device. The perpendicular component may be a component of the light propagation direction perpendicular to the light-generating region (e.g., active layer) and/or the emission surface of the light-emitting device.

The feedback element may include a polarizer, such as a reflective polarizer (e.g., a wire-grid polarizer), a reflective cavity having one or more transmissive regions or apertures, and/or a wavelength filter (e.g., a multi-layer dielectric and/or semiconductor stack, dichroic mirror). In some embodiments, the feedback element includes at least one polarizer (e.g., reflective polarizer) and the light-emitting system may recycle light so as to enhance the emission of light having a desired polarization state. In some embodiments, the feedback element includes at least one optical cavity that may include one or more transmissive regions (e.g., one or more apertures, such as windows) and/or one or more optical elements (e.g., one or more prisms, an array or prism, an array of micro-prisms) and the light-emitting system may recycle light so as to enhance the emission of light having a desired propagation direction (and/or a range of propagation directions). In some embodiments, the feedback element includes one or more wavelength filter(s) (e.g., long wavelength filter, short wavelength filter, and/or band-pass wavelength filter) and the light-emitting system may recycle light so as to enhance the emission of light having a one or more desired wavelengths or ranges of wavelengths.

The feedback element may return (e.g., reflect back) or output (e.g., transmit) light based one or more optical properties or characteristics. For example, a wavelength filter (e.g., a multi-layer dielectric and/or semiconductor stack, dichroic mirror) may reflect or transmit light based on wavelength and/or light propagation direction, as the light transmission properties of the wavelength filter may vary with the normal angle of incidence of light that impinges on the wavelength filter, where the normal angle of incidence is related to the light propagation direction.

In some embodiments, the light-emitting system may include one or more wavelength conversion regions that can convert at least some light from a first range of wavelengths to a second range of wavelengths. Wavelength conversion regions may be part of a light-emitting device or system that includes one or more feedback elements, as described further below. One or more of the wavelength conversion regions can be located in an optical path between a light-emitting device (e.g., the emission surface or the active region of the light-emitting die) and one or more feedback elements.

In some embodiments, the feedback element may include a plurality of feedback elements. The plurality of feedback elements may be configured to return back (e.g., reflect back) and/or output (e.g., transmit) at least some light based on one or more characteristics of the light incident thereon. The plurality of feedback elements may be arranged in succession so that a given feedback element may act on (e.g., return or output) the light that can be provided by a previous feedback element. For example, the plurality of feedback elements may be arranged one over the other to form a stack of feedback elements. A stack of feedback elements may be disposed over a light emission surface of a light-emitting device.

Such configurations can enable light emitted by the light-emitting device to be recycled such that a larger percentage of light emitted by the combined system (e.g., including the light-emitting device and the feedback element) has one or more desired characteristic(s) (e.g., a desired polarization, a desired propagation direction, and/or a desired wavelength). In some embodiments, one or more of the feedback elements return (e.g., reflect) substantially all light having a first characteristic state and output (e.g., transmit) substantially all light having a second characteristic state.

The light-emitting system (e.g., the light-emitting device and/or elements external to the device) can include a manipulation region 130 that can alter one or more characteristics (e.g., polarization, propagation direction, and/or wavelength) of light that is returned back by one or more feedback elements. Modification of the light characteristic(s), such as polarization, may be performed by a manipulation region that alters the polarization in the same way and/or a different way for light impinging on different locations of the manipulation region. For example, with regards to polarization, a phase retarder, such as a quarter wave plate, alters the polarization in a manner such that polarization is altered in the same way for light impinging on all locations of the phase retarder. In contrast, a patterned surface, such as a two-dimensional pattern of features (e.g., a pattern of holes and/or posts, as discussed further below), may alter the polarization such that the polarization can be altered in a different way for light impinging on different locations of the patterned surface.

The manipulation region can include one or more portions of the light-emitting device, including but not limited to, one or more layers of the light-emitting device. In some embodiments, the manipulation region can comprise a plurality of features. In some embodiments, the plurality of features may be surface features. In some embodiments, the plurality of features may result in a dielectric function that varies spatially according to a pattern. In some embodiments, the pattern may be non-periodic. The manipulation region can include one or more patterned layers, one or more roughened layers, one more diffuse and/or specular reflective regions, one or more phase retarders or shifters (e.g., quarter wave plates, half wave plates), and/or one or more wavelength converting regions. A patterned layer can include a layer having a dielectric function that varies according to a pattern, as described further below.

In the example illustrated in FIG. 1, the light-emitting device or system may include a manipulation region 130 that includes the emission surface. Manipulation region 130 may include a layer or region having a dielectric function that varies spatially according to a pattern. In some embodiments, manipulation region 130 may include a layer or region having a roughened surface. In other embodiments, manipulation region 130 may be absent. Manipulation region 130 may be part of an underlying layer 122 or may be formed of a material different from the underlying layer 122. As illustrated in FIG. 1, manipulation region 130 may be located, partially or completely, between light-generating region 120 and feedback element 140. Such a configuration can achieve light recycling as the manipulation region can effectively alter the state (e.g., polarization, propagation direction) of light returned by the feedback element.

During operation of light-emitting system 100, light 10 may be generated by the light-generating region 120 and impinge upon the feedback element 140. Light that impinges on the feedback element 140 may have a first characteristic state, a second characteristic state, or a combination thereof. In some embodiments, the first and second characteristic states can be a first polarization and a second polarization, such as a first linear polarization state and a second linear polarization state, wherein the first and the second linear polarization states can be orthogonal. In some embodiments, the first and second characteristic states can be a first and second propagation direction range (e.g., range of angles), respectively. In some embodiments, the first and second characteristic states can be a first and second wavelength range, respectively. FIG. 1 illustrates various situations of light rays 10, 12, and 14 impinging on feedback element 140. Depending on the characteristic state of the light, the light can be outputted (e.g., transmitted) or returned back (e.g., reflected) by the feedback element 140.

Light ray 10 illustrates a situation where the light has a characteristic state that is at least partially transmitted (e.g., substantially all transmitted) by the feedback element 140 and thus at least some (e.g., substantially all) of light 10 is transmitted by the feedback element 140.

Light ray 12 illustrates another situation where the generated light has a characteristic state that is at least partially or completely returned back (e.g., reflected) by the feedback element 140 and thus at least some or all of light 12 is returned back (e.g., reflected) by the feedback element 140. Light 12 may then impinge on a manipulation region that can alter the state of the characteristic of the light. For example, the returned light can be manipulated by a manipulation region 130. In some embodiments, the manipulation region 130 includes one or more patterned layers, one or more a roughened layers, one more diffuse and/or specular reflectors, one or more phase retarders or shifters (e.g., quarter wave plates, half wave plates), and/or one or more wavelength converting regions.

Upon impinging on manipulation region 130, light 12 may be reflected back towards the feedback element 140 and may be outputted (e.g., transmitted) by the feedback element if the characteristic state of the light was altered (e.g., by the manipulation region 130) to have a state that is outputted by the feedback element 140. It should be appreciated that the manipulation region can be located at any location of the light-emitting device and/or the system.

Light ray 14 illustrates a situation where the light generated by the light-generating region has a characteristic state that is at least partially or completely returned (e.g., reflected) by the feedback element, and may be manipulated by the manipulation region and then reflected back towards the feedback element 140 by the reflective layer 150 on the backside of the device 110. Light 14 may be outputted (e.g., transmitted) by the feedback element if the characteristic state of the light was altered (e.g., by the manipulation region 130) to have a state that is transmitted by the feedback element 140 (e.g., the second characteristic state).

The configuration of light-emitting system 100 can establish a light recycling cavity (e.g., between feedback element 140 and emission surface 138 and/or between feedback element 140 and reflective layer 150). The recycling cavity can manipulate one or more characteristics of the light within the cavity such that a substantial portion (e.g., greater than 50%, greater than 70%, greater than 90%) of the light outputted by the system 100 has a desired characteristic state (e.g., polarization, propagation direction, and/or wavelength). In some embodiments, the desired characteristic state can include a range of states (e.g., a range of polarizations, a range of propagation directions, and/or a range of wavelengths).

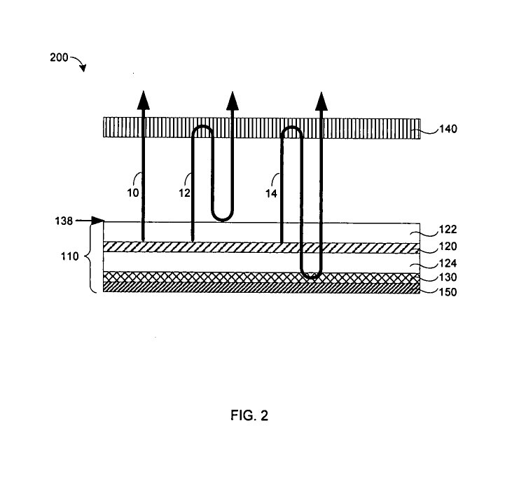

FIG. 2 illustrates an embodiment of a light-emitting system 200 in accordance with one embodiment. Light-emitting system 200 is similar to light-emitting device 100 except that the manipulation region 130 may be disposed under the light-generating region 120. In some embodiments, at least a portion, or all, of the manipulation region 130 may be disposed in contact with reflective layer 150. Alternatively, or additionally, at least a portion, or all, of manipulation region 130 may be disposed in contact or within layer 124 and/or light-generating region 120.

It should be appreciated that although the manipulation region 130 can alter the characteristic state of light impinging thereon, one or more other portions of the system or the light-emitting device 110 can alternatively, or additionally, alter the characteristic state of the light. For example, the characteristic state of the light may be altered by emission surface 138, as illustrated for the situation of light ray 12, where light returned back (e.g., reflected back) by the feedback element may then have its characteristic state altered upon impinging on emission surface 138. In the illustrated situation for light ray 12, light impinging on surface 138 (after being returned back by feedback element 140) may be reflected with a modified characteristic state (e.g., by reflective regions, for example, by one or more semiconductor and/or metal regions). Some of the light returned back towards the emission surface 138 may be transmitted into the light-emitting device 110, as illustrated for light ray 14. Such light may then be modified by one or more regions of the system, including, but not limited to, manipulation region 130 illustrated in FIG. 2.

In some embodiments, the manipulation region 130 includes the reflective layer 150. Reflective layer 150 may serve as a manipulation region (e.g., for polarization and/or propagation direction, including but not limited to the tangentential component of the light propagation direction). In some embodiments, reflective layer 150 may include one or more regions that are diffuse reflectors and/or one or more regions that are specular reflectors. In some embodiments, reflective layer 150 is a diffuse reflector that extends over the area of the device 110 backside. In some embodiments, reflective layer 150 is a specular reflector that extends over the area of the device backside.

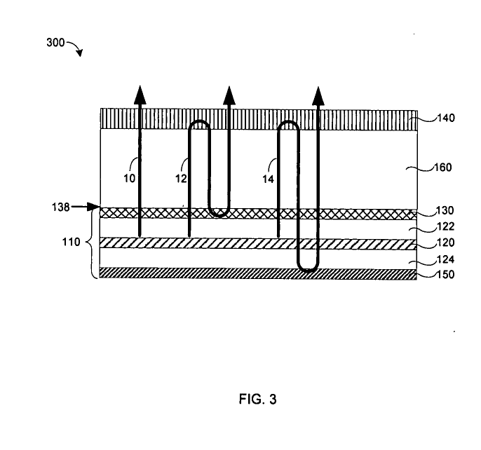

FIG. 3 illustrates an embodiment of a light-emitting system 300 in accordance with one embodiment. Light-emitting system 300 is similar to light-emitting system 100 except that a material region 160 may be disposed between feedback element 140 and manipulation region 130. In some embodiments, material region 160 may be disposed between feedback element 140 and emission surface 138 of light-emitting device 110. Material region 160 may be in direct contact with emission surface 138 and/or feedback element 140.

Material region 160 may serve as part or all of an optical cavity that may serve as part or all of a light recycling cavity. The optical cavity can enable the recycling of light such that a majority (e.g., greater than about 50%, greater than about 70%, greater than 90%, or substantially all) of the light emitted by light-emitting system 300 has a desired characteristic state (e.g., polarization, propagation direction, and/or wavelength).

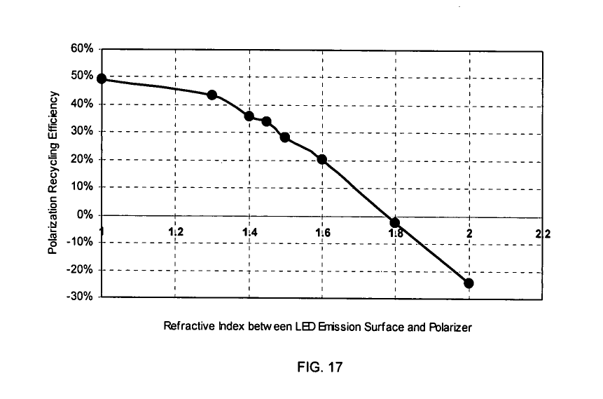

The index of refraction and/or the thickness (e.g., distance between feedback element 140 and emission surface 138, for example the thickness of material layer 160) of the optical cavity formed between feedback element 140 and emission surface 138 of the light-emitting device, may determine whether light recycling achieves more light emission (e.g., from the system 300) with the desired characteristic state than would be emitted if material layer 160 and feedback element 140 were absent. One aspect of some embodiments presented herein is that there exist critical range(s) of indices of refraction and/or thicknesses of material region 160 which can achieve marked light recycling as compared to indices of refraction and/or thicknesses outside of the critical range(s). This result is unexpected as the conventional practice in the art is that the distance between a polarizer relative a light source and the refractive index of the separation medium is irrelevant regarding the operation of such an assembly. Examples of simulation results illustrating the critical ranges for light recycling are described further below, with reference to FIGS. 17-19.

In some embodiments, material region 160 may have an index of refraction of less than about 2.6 (e.g., less than about 2.4, less than about 2.2, less than about 2.0, less than about 1.8, less than about 1.6, less than about 1.5, less than about 1.4, less than about 1.3, less than about 1.2) which can result in substantial light recycling. In some embodiments, material region 160 may have an index of refraction of less than about 0.8 times (e.g., less than about 0.75, less than about 0.7, less than about 0.65, less than about 0.6, less than about 0.5) the index of refraction of the emission surface of the light-emitting device (e.g., the material that forms the emission surface 138) which may result in substantial light recycling. Examples of the refractive index of the emission surface of the light-emitting device may include less than about 2.6 and greater than about 2.0 for typical GaN-based light-emitting devices, and less than about 3.6 and greater than about 3.0 for typical AInGaP-based light-emitting device.

In some embodiments, the material region 160 can have a thickness of less than about 2.5 microns (e.g., less than about 2.0 microns) and/or greater than about 0.5 microns (e.g., greater than about 0.75 microns, greater than about 1.0 microns, greater than about 1.5 microns) which can result in substantial light recycling.

Material region 160 may include one or more materials. For example, material region 160 may include a plurality of materials layers. The plurality of material layers may be disposed at least partially over each other. Material region 160 may include composite materials. Composite materials may include multi-layered materials and/or materials having dispersed particles within a host matrix. For example, material region 160 may include nanostructures, such as quantum dots, nanowires, and/or nanorods (e.g., semiconductor, dielectric and/or metal nanostructures) dispersed in a host material matrix (e.g., oxide, spin-on-glass, silicon dioxide, silicon nitride, silicon oxynitride). In some embodiments, material region 160 may include a porous material. For example, material region 160 may include a nanoporous material. Examples of nano-porous silica materials and methods of making these materials are provided, for example in, U.S. Pat. No. 6,048,804, entitled “Process for producing nanoporous silica thin films,” filed on Apr. 3, 1998, which is herein incorporated by reference in its entirety.

Material region 160 may include one or more electrically insulating materials (e.g., dielectric materials), one or more semiconductors, and/or one or more metals. Material region 160 may include one or more oxides (e.g., silicon oxide, spin-on-glass, fused silica, silicon-oxynitride), one or more epoxy-based materials, and/or one or more organic or inorganic polymers (e.g., photo-resists, for example SU-8, polyimide). Material region 160 may include group III, group IV, group V semiconductors, or combinations thereof (e.g., group III-V semiconductors, group II-IV semiconductors). Material region 160 may include a ferromagnetic material (e.g., possessing magnetic permeability different from unity) and/or paramagnetic material. Material region 160 may include an anisotropic material, for example a birefringent material. Material region 160 may include one or more wavelength converting materials, for example one or more phosphors and/or nanostructures (e.g., quantum dots, nanowires, nanorods). Material region 160 may include active materials, for example, materials having optical gain properties.

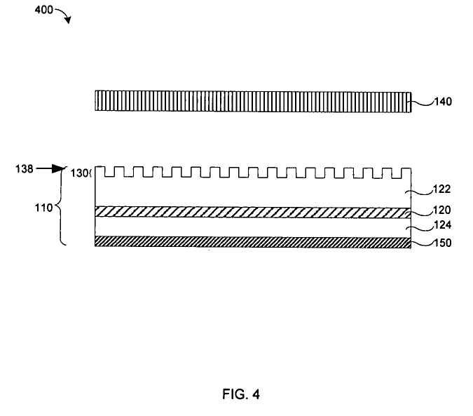

FIG. 4 illustrates a light-emitting system 400 similar to light-emitting system 100 except that light-emitting device 110 includes a dielectric function that can vary according to a pattern, in accordance with one embodiment. For example, the light-emitting device 110 can include an emission surface 138 having a dielectric function that can vary along one, two, or three dimensions according to a pattern. For example, the dielectric function can vary as a function of both dimensions that may specify an emission surface.

In some embodiments, the pattern forms part or all of the manipulation region 130 that can alter one or more characteristic states of light impinging thereon. For example, the pattern can effectively alter the polarization state and/or propagation direction of light impinging thereon. By altering the propagation direction, the pattern can alter the collimation of the light (e.g., the angle of the light propagation direction with respect to a surface normal of the emission surface 138).

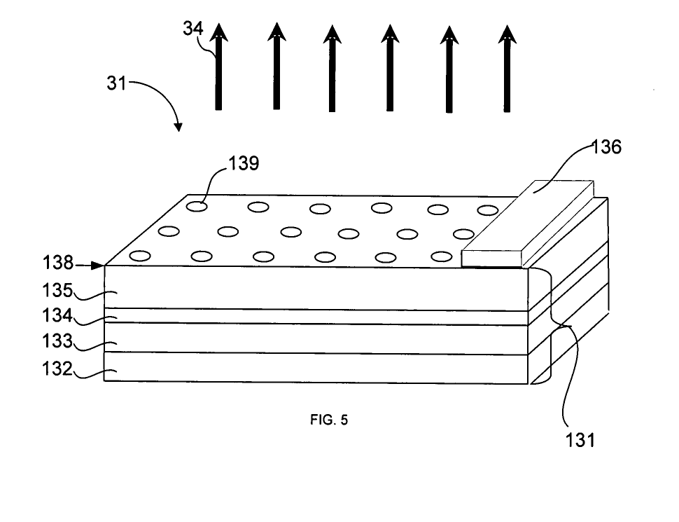

FIG. 5 illustrates a light-emitting diode (LED) which may be one example of a light-emitting device, in accordance with one embodiment. It should be understood that various embodiments presented herein can also be applied to other light-emitting devices, such as laser diodes, and LEDs having different structures (such as organic LEDs, also referred to as OLEDs). LED 31 shown in FIG. 5 comprises a multi-layer stack 131 that may be disposed on a support structure (not shown). The multi-layer stack 131 can include an active region 134 which is formed between n-doped layer(s) 135 and p-doped layer(s) 133. The stack can also include an electrically conductive layer 132 which may serve as a p-side contact, which can also serve as an optically reflective layer. An n-side contact pad 136 may be disposed on layer 135. Electrically conductive fingers (not shown) may extend from the contact pad 136 and along the surface 138, thereby allowing for uniform current injection into the LED structure.

It should be appreciated that the LED is not limited to the configuration shown in FIG. 5, for example, the n-doped and p-doped sides may be interchanged so as to form a LED having a p-doped region in contact with the contact pad 136 and an n-doped region in contact with layer 132. As described further below, electrical potential may be applied to the contact pads which can result in light generation within active region 134 and emission of at least some of the light generated through an emission surface 138. As described further below, holes 139 may be defined in an emission surface to form a pattern that can influence light emission characteristics, such as light extraction and/or light collimation. It should be understood that other modifications can be made to the representative LED structure presented, and that embodiments are not limited in this respect.

The active region of an LED can include one or more quantum wells surrounded by barrier layers. The quantum well structure may be defined by a semiconductor material layer (e.g., in a single quantum well), or more than one semiconductor material layers (e.g., in multiple quantum wells), with a smaller electronic band gap as compared to the barrier layers. Suitable semiconductor material layers for the quantum well structures can include InGaN, AlGaN, GaN and combinations of these layers (e.g., alternating InGaN/GaN layers, where a GaN layer serves as a barrier layer). In general, LEDs can include an active region comprising one or more semiconductors materials, including III-V semiconductors (e.g., GaAs, AlGaAs, AlGaP, GaP, GaAsP, InGaAs, InAs, InP, GaN, InGaN, InGaAlP, AlGaN, as well as combinations and alloys thereof), II-VI semiconductors (e.g., ZnSe, CdSe, ZnCdSe, ZnTe, ZnTeSe, ZnS, ZnSSe, as well as combinations and alloys thereof), and/or other semiconductors. Other light-emitting materials are possible such as quantum dots or organic light-emission layers.

The n-doped layer(s) 135 can include a silicon-doped GaN layer (e.g., having a thickness of about 4000 nm thick) and/or the p-doped layer(s) 133 include a magnesium-doped GaN layer (e.g., having a thickness of about 40 nm thick). The electrically conductive layer 132 may be a silver layer (e.g., having a thickness of about 100 nm), which may also serve as a reflective layer (e.g., that reflects upwards any downward propagating light generated by the active region 134). Furthermore, although not shown, other layers may also be included in the LED; for example, an AlGaN layer may be disposed between the active region 134 and the p-doped layer(s) 133. It should be understood that compositions other than those described herein may also be suitable for the layers of the LED.

As a result of holes 139, the LED can have a dielectric function that varies spatially according to a pattern. Typical hole sizes can be less than about one micron (e.g., less than about 750 nm, less than about 500 nm, less than about 250 nm) and typical nearest neighbor distances between holes can be less than about one micron (e.g., less than about 750 nm, less than about 500 nm, less than about 250 nm). Furthermore, as illustrated in the figure, the holes 139 can be non-concentric.

The dielectric function that varies spatially according to a pattern can influence the extraction efficiency and/or collimation of light emitted by the LED. In some embodiments, a layer of the LED may have a dielectric function that varies spatially according to a pattern. In the illustrative LED 31, the pattern is formed of holes, but it should be appreciated that the variation of the dielectric function at an interface need not necessarily result from holes. Any suitable way of producing a variation in dielectric function according to a pattern may be used. For example, the pattern may be formed by varying the composition of layer 135 and/or emission surface 138. The pattern may be periodic (e.g., having a simple repeat cell, or having a complex repeat super-cell), or non-periodic. As referred to herein, a complex periodic pattern is a pattern that has more than one feature in each unit cell that repeats in a periodic fashion. Examples of complex periodic patterns include honeycomb patterns, honeycomb base patterns, (2×2) base patterns, ring patterns, and Archimedean patterns. In some embodiments, a complex periodic pattern can have certain holes with one diameter and other holes with a smaller diameter. As referred to herein, a non-periodic pattern is a pattern that has no translational symmetry over a unit cell that has a length that is at least 50 times the peak wavelength of light generated by one or more light-generating portions. As used herein, peak wavelength refers to the wavelength having a maximum light intensity, for example, as measured using a spectroradiometer. Examples of non-periodic patterns include aperiodic patterns, quasi-crystalline patterns (e.g., quasi-crystal patterns having 8-fold symmetry), Robinson patterns, and Amman patterns. A non-periodic pattern can also include a detuned pattern (as described in U.S. Pat. No. 6,831,302 by Erchak, et al., which is incorporated herein by reference). In some embodiments, a device may include a roughened surface. The surface roughness may have, for example, a root-mean-square (rms) roughness about equal to an average feature size which may be related to the wavelength of the emitted light.

In certain embodiments, an interface of a light-emitting device is patterned with holes which can form a photonic lattice. Suitable LEDs having a dielectric function that varies spatially (e.g., a photonic lattice) have been described in, for example, U.S. Pat. No. 6,831,302 B2, entitled “Light emitting devices with improved extraction efficiency,” filed on Nov. 26, 2003, which is herein incorporated by reference in its entirety. A high extraction efficiency for an LED implies a high power of the emitted light and hence high brightness which may be desirable in various optical systems.

It should also be understood that other patterns are also possible, including a pattern that conforms to a transformation of a precursor pattern according to a mathematical function, including, but not limited to an angular displacement transformation. The pattern may also include a portion of a transformed pattern, including, but not limited to, a pattern that conforms to an angular displacement transformation. The pattern can also include regions having patterns that are related to each other by a rotation. A variety of such patterns are described in U.S. Patent Publication No. 20070085098, entitled “Patterned devices and related methods,” filed on Mar. 7, 2006, which is herein incorporated by reference in its entirety.

Light may be generated by the LED as follows. The p-side contact layer can be held at a positive potential relative to the n-side contact pad, which causes electrical current to be injected into the LED. As the electrical current passes through the active region, electrons from n-doped layer(s) can combine in the active region with holes from p-doped layer(s), which can cause the active region to generate light. The active region can contain a multitude of point dipole radiation sources that generate light with a spectrum of wavelengths characteristic of the material from which the active region is formed. For InGaN/GaN quantum wells, the spectrum of wavelengths of light generated by the light-generating region can have a peak wavelength of about 445 nanometers (nm) and a full width at half maximum (FWHM) of about 30 nm, which is perceived by human eyes as blue light. The light emitted by the LED may be influenced by any patterned surface through which light passes, whereby the pattern can be arranged so as to influence light extraction and/or collimation.

In other embodiments, the active region can generate light having a peak wavelength corresponding to ultraviolet light (e.g., having a peak wavelength of about 370-390 nm), violet light (e.g., having a peak wavelength of about 390-430 nm), blue light (e.g., having a peak wavelength of about 430-480 nm), cyan light (e.g., having a peak wavelength of about 480-500 nm), green light (e.g., having a peak wavelength of about 500 to 550 nm), yellow-green (e.g., having a peak wavelength of about 550-575 nm), yellow light (e.g., having a peak wavelength of about 575-595 nm), amber light (e.g., having a peak wavelength of about 595-605 nm), orange light (e.g., having a peak wavelength of about 605-620 nm), red light (e.g., having a peak wavelength of about 620-700 nm), and/or infrared light (e.g., having a peak wavelength of about 700-1200 nm).

In certain embodiments, the LED may emit light having a high light output power. As previously described, the high power of emitted light may be a result of a pattern that influences the light extraction efficiency of the LED. For example, the light emitted by the LED may have a total power greater than 0.5 Watts (e.g., greater than 1 Watt, greater than 5 Watts, or greater than 10 Watts). In some embodiments, the light generated has a total power of less than 100 Watts, though this should not be construed as a limitation of all embodiments. The total power of the light emitted from an LED can be measured by using an integrating sphere equipped with spectrometer, for example a SLM12 from Sphere Optics Lab Systems. The desired power depends, in part, on the optical system that the LED is being utilized within. For example, a display system (e.g., a LCD system) may benefit from the incorporation of high brightness LEDs which can reduce the total number of LEDs that are used to illuminate the display system.

The light generated by the LED may also have a high total power flux. As used herein, the term “total power flux” refers to the total optical power divided by the emission area. In some embodiments, the total power flux is greater than 0.03 Watts/mm², greater than 0.05 Watts/mm², greater than 0.1 Watts/mm², or greater than 0.2 Watts/mm². However, it should be understood that the LEDs used in systems and methods presented herein are not limited to the above-described power and power flux values.

In some embodiments, the LED may be associated with one or more wavelength converting regions. The wavelength converting region(s) may include one or more phosphors and/or quantum dots. The wavelength converting region(s) can absorb light emitted by the light-generating region of the LED and emit light having a different wavelength than that absorbed. In this manner, LEDs can emit light of wavelength(s) (and, thus, color) that may not be readily obtainable from LEDs that do not include wavelength converting regions. In some embodiments, one or more wavelength converting regions may be disposed over (e.g., directly on) the emission surface (e.g., surface 138) of the light-emitting device.

As used herein, an LED may be an LED die, a partially packaged LED die, or a fully packaged LED die. It should be understood that an LED may include two or more LED dies associated with one another, for example a red light-emitting LED die, a green light-emitting LED die, a blue light-emitting LED die, a cyan light-emitting LED die, or a yellow light-emitting LED die. For example, the two or more associated LED dies may be mounted on a common package. The two or more LED dies may be associated such that their respective light emissions may be combined to produce a desired spectral emission. The two or more LED dies may also be electrically associated with one another (e.g., connected to a common ground).

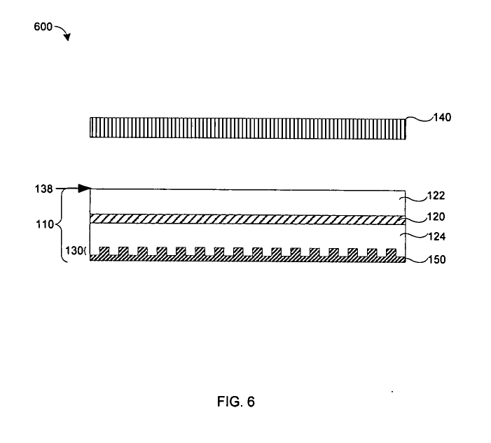

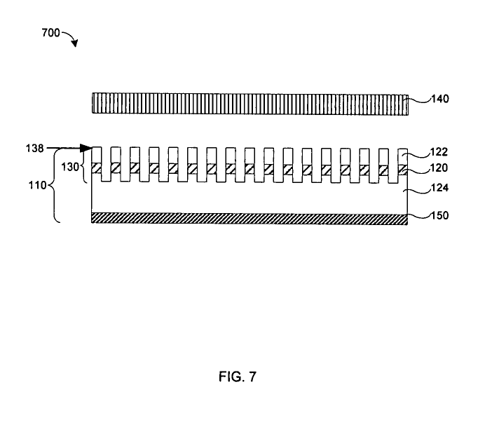

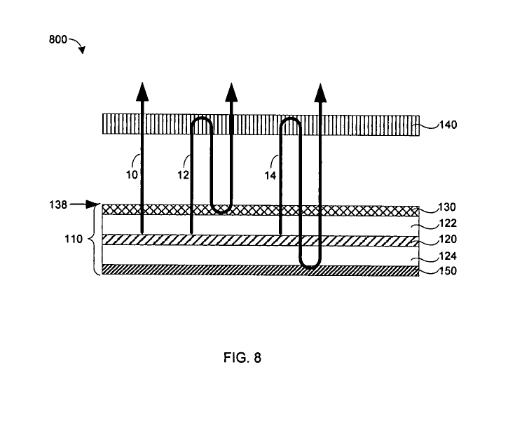

FIG. 6 illustrates a light-emitting system 600, in accordance with one embodiment. Light-emitting system 600 is similar to light-emitting system 200 where manipulation region 130 may be disposed under the light-generating region 120. In light-emitting system 600, the light-emitting device 110 may include a dielectric function that varies according to a pattern disposed under the light-generating region 120. In some embodiments, the pattern may in part or in whole be in contact with backside reflective layer 150.

FIG. 7 illustrates a light-emitting system 700, in accordance with one embodiment. Light-emitting system 700 is similar to light-emitting system 400 except that the dielectric function that varies spatially according to a pattern can intersect light-generating region 120 (e.g., active region). Sidewalls of the exposed active region and layer 124 can be insulated with an electrically insulating material (e.g., one or more dielectrics), and a top electrical contact (e.g., metal, transparent conductive materials such as indium tin oxide) can be disposed in contact with a portion or all of layer 122 so as to provide for electrical injection.

It should be appreciated that combinations of one or more features of embodiments presented herein are possible. For example, a pattern on the backside portion of the light-emitting device can extend into at least partially into the light-generating region of the device. In another example, a pattern may be present both over the light-generating region and under the light-generating region. More generally, a manipulation region may be present over, under, and/or may intersect the light-generating region.

One or more elements of the light-emitting systems described herein may be integrated as part of a light-emitting device such that light recycling may be performed on the device and/or device package level. In some embodiments, a light-generating region, a feedback element, and a manipulation element may be part of a light-emitting device and/or a package of the light-emitting device. In some embodiments, a light-generating region, a feedback element, and a manipulation element may be part of a light-emitting die of a light-emitting device.

In some embodiments, a feedback element of a light-emitting system may include at least one polarizer (e.g., a reflective polarizer). The one or more polarizer(s) may enhance the light emission of the light-emitting system having a particular polarization state.

FIG. 8 illustrates a light-emitting system 800 including a light-generating region 120 of a light-emitting device 110, in accordance with one embodiment. The light-emitting device may include a polarization manipulation region 130. In some embodiments, the polarization manipulation region may include a layer having a dielectric function that varies spatially according to a pattern.

Light-emitting system 800 can include a polarization feedback element 140 that returns back (e.g., reflects back) at least some light having a first polarization state and outputs (e.g., transmits) at least some light having a second polarization state. In some embodiments, the feedback element includes at least one polarizer. As used herein, it should be understood that a polarizer includes one or more portions that provide for polarization of impinging light. In some embodiments, the feedback element includes at least one reflective polarizer, for example, one or more wire-grid polarizer(s). A wire-grid polarizer may be formed of a plurality of reflective material lines (e.g., metal lines, high refractive index material lines) which may be arranged in a parallel configuration. The reflective lines (e.g., metal lines) and the spacing between the reflective lines may have dimensions such that light (e.g., visible light) having a linear polarization state such that the light's electric field is aligned along the reflective lines is reflected by the wire-grid polarizer and light having a linear polarization state such that the light's electric field is perpendicular to the reflective lines is transmitted by the wire-grid polarizer.

In some embodiments, feedback element 140 may include a plurality of polarizers. The plurality of polarizers may be configured and arranged to return (e.g., reflect) and/or output (e.g., transmit) at least some light depending on the polarization state of the light incident thereon. The plurality of polarizers may be arranged in succession so that a given polarizer may act (e.g., return back or output) on the light that is outputted by a previous polarizer. Such a configuration enables light emitted by the light-emitting system to be enhanced for a desired polarization. When a plurality of polarizers are present, some or all of the polarizers may be part of the light-emitting device and/or the package of the light-emitting device. In one embodiment, at least two polarizers are arranged to transmit light having substantially the same polarization state, for example, two or more wire-grid polarizers may have reflective lines that are parallel with each other. Two or more polarizers may serve to enhance the extinction ratio of light from the light-emitting system. In some embodiments, the at least two polarizers are integrated in a light-emitting device and/or a package of the light-emitting device.

During operation, light ray 10 may be generated by the light-generating region 120 and impinge upon the feedback 140 that includes at least one polarizer. Light 10 has a polarization state that is at least partially transmitted by the feedback element 140 and thus at least some (or substantially all) of light 10 is transmitted by the feedback element 140. In another situation, light ray 12 may be generated by the light-generating region 120 and impinge upon the feedback element 140. Light 12 has another polarization state that is at least partially returned back (e.g., reflected back) by feedback element 140 and thus at least some or all of light 12 is returned back (e.g., reflected) by feedback element 140. Light 12 may be manipulated by the polarization manipulation region 130 (e.g., one or more patterned layers, one or more roughened layers, one more diffuse and/or specular reflectors, one or more phase retarders or shifters) such that the state of the polarization is altered. Light 12 may be reflected back towards the feedback element 140 and may be transmitted by the feedback element if the polarization state of the light is altered to have a state that is outputted by the feedback element 140. Light ray 14 illustrates another situation where the light generated by the light-generating region has a polarization state that is returned back (in part or in whole) by the feedback element, and may be manipulated by the polarization manipulation region 130 and reflected back towards the feedback element 140 by reflective layer 150.

Although FIG. 8 illustrates a polarization manipulation region 130 which may be disposed over the light-generating region 120, other arrangements are possible. For example, polarization manipulation region 130 may be disposed under the light-generating region 120 and in some embodiments may be in contact with a backside reflective layer 150. In other embodiments, polarization manipulation region 130 may intersect at least a portion of the light-generating region 120.

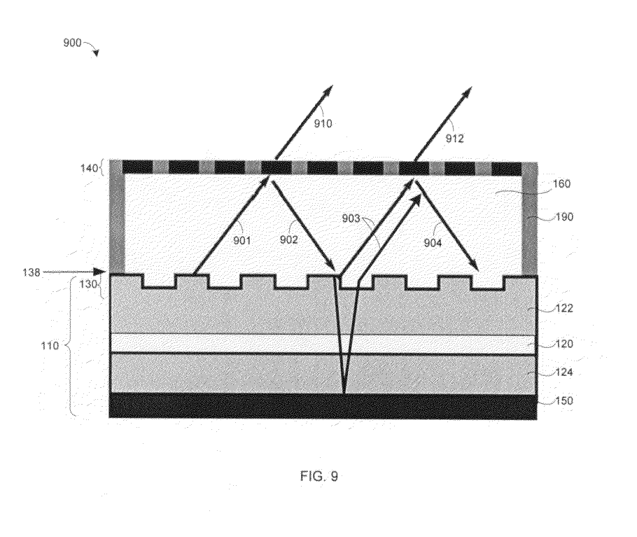

FIG. 9 illustrates an embodiment of a light-emitting device 900 where a feedback element 140 may be part of a package that supports or houses light-emitting device 110. Feedback element 140 may be part of a window of a package that supports, houses, and/or protects light-emitting device 110. Feedback element 140 may be supported by frame 190 of the package, which can define a precise separation distance between the feedback element 140 and the emission surface 138 of the light-emitting device 110. As used herein, separation distance refers to the minimum separation distance. Frame 190 can be reflective, and the interior walls of frame 190 may include specular and/or diffuse reflective regions.

Feedback element 140 may include a polarizer, for example a reflective polarizer (e.g., a wire-grid polarizer). The polarizer may be a wire-grid polarizer that may be formed on (e.g., a top side, a bottom side, or both top and bottom sides) and/or within a window, such as a transparent glass window. In some embodiments, a first wire-grid polarizer may be formed on one side of the window substrate and a second wire-grid polarizer may be formed on the other side of the window substrate.

In some embodiments, a polarizer (e.g., a reflective polarizer, such as a wire-grid polarizer) may be separated from the emission surface 138 of the light-emitting device 110 by a medium (e.g., a material region 160) having a refraction index of less than about 2.6 (e.g., less than about 2.4, less than about 2.2, less than about 2.0, less than about 1.8, less than about 1.6, less than about 1.5, less than about 1.4, less than about 1.3). In some embodiments, the medium (e.g., material region 160) may have an index of refraction of less than about 0.8 times (e.g., less than about 0.75, less than about 0.7, less than about 0.65, less than about 0.6, less than about 0.5) the index of refraction of the emission surface of the light-emitting device (e.g., refractive index of layer 122). As referred to herein, the index of refraction of a material may be measured using ellipsometry.

In some embodiments, the medium separating feedback element 140 and emission surface 138 includes one or more gases (e.g., air, nitrogen, noble gas) or a vacuum. The medium separating feedback element 140 and emission surface 138 can form an optical cavity which may be hermetically sealed. A hermetically sealed cavity (e.g., filled with an inert gas, such as nitrogen) may be beneficial when a reflective polarizer is disposed within the sealed cavity (e.g., on the interior surface of a window) and is formed of a material that may be reactive to air (e.g., silver).

Feedback element 140 may be separated from the emission surface 138 by greater than about 0.1 microns (e.g., greater than about 0.25 microns, greater than about 0.5 microns, greater than about 0.75 microns, greater than about 1.0 microns, greater than about 1.5 microns, greater than about 2.0 microns). Feedback element 140 may be separated from emission surface 138 by less than about 5.0 microns (e.g., less than about 4.0 microns, less than about 3.0 microns, less than about 2.5 microns, less than about 2.0 microns).

Feedback element 140 may be separated from emission surface of 138 by greater than about a peak wavelength of light emitted by the light-emitting device (e.g., greater than about 1.5 times the peak wavelength, greater than about 2 times the peak wavelength, greater than about 3 times the peak wavelength, greater than about 4 times the peak wavelength). Feedback element 140 may be separated from emission surface 138 by less than about 10 times a peak wavelength of light emitted by the light-emitting device (e.g., less than about 8 times the peak wavelength, less than about 6 times the peak wavelength, less than about 5 times the peak wavelength, less than about 4 times the peak wavelength). In some embodiments, the peak wavelength of the emitted light may be blue light having a peak wavelength of about 460 nm, green light having a peak wavelength of about 525 nm, and/or red light having a peak wavelength of about 625 nm.

As illustrated by the schematic of FIG. 9, light-emitting device 110 can include a polarization manipulation region 130 having a dielectric function that varies spatially according to a pattern. Such a patterned layer may be located at any location on and/or within the light-emitting device. Although such a pattern may serve as part or all of a light manipulation region, the light-emitting device need not necessarily include a pattern.

During operation, light 901 generated in light-generating region 120 can be emitted through emission surface 138 and may impinge on feedback element 140. Light 901 may include a plurality of polarization states. For example, a first portion of light 901 may be S polarized light, and a second portion of light 901 may be P polarized light. Feedback element 140 may be arranged such that P polarized light is substantially transmitted (arrow 910) and S polarized light is substantially reflected (arrow 902). Reflected light 902 may impinge back onto emission surface 138 of light-emitting device 110. Some or all of light 902 may be reflected by emission surface 138. Alternatively, or additionally, some or all of light 902 may travel through the material stack of light-emitting device 110, be reflected by reflective layer 150, and may emerge once more from emission surface 138. Irrespective of path taken, light 903 may impinge upon the feedback element 140, however at least part or all of the light may have experienced a change in polarization state, for example via interaction with manipulation region 130, and thus a part of light 903 having a P polarization state may be transmitted (arrow 912) by feedback element 140 and the remainder of the light 903 having a S polarization state may be reflected (arrow 904).

Such a process of polarization recycling can proceed until substantially all of emitted light 901 is recycled and transmitted by feedback element 140 or absorbed within device 110, feedback element 140, and/or frame 190. For example, if light reflecting back into light-emitting device 110 has the same wavelength as upon generation, the light may be absorbed by light-generating region 120 (e.g., active region). To alleviate this source of light loss, at least part or all of the generated light may be down-converted to a lower energy (e.g., longer wavelength) such that the light is not absorbed by light-generating region 120 (e.g., the light has a smaller energy than the band-gap of the active region). Down-conversion may occur upon interaction of light with one or more wavelength converting regions. In some embodiments, part, or all, of the medium between feedback element 140 and emission surface 138 includes one or more wavelength converting regions which can down-convert light. Alternatively, or additionally, regions between reflective layer 150 and layer 124 of the material stack may include wavelength converting materials. For example, layer 124 may include patterned holes within which wavelength converting material may reside.

Manipulation of the light polarization state may be due to interaction of the light with a part of light-emitting device 110 and/or the medium separating feedback element 140 and emission surface 138. In some embodiments, the polarization manipulation of the light can be due to, in part or in whole, a pattern of the light-emitting device, for example, a layer having a dielectric function that varies according to a pattern. In some embodiments, the polarization manipulation of the light can be due to, in part or in whole, roughness of a layer of the light-emitting device, for example roughness of emission surface 138. In some embodiments, the polarization manipulation of the light can be due to, in part or in whole, reflective layer 150, which may include a diffuse reflector. In some embodiments, the polarization manipulation of the light can be due to, in part or in whole, one or more materials that may be disposed between feedback element 140 and emission surface 138, including microstructures and/or nanostructures (e.g., semiconductor, metal, and/or dielectric quantum dots, nanowires, or nanorods) and/or wavelength converting materials such as phosphor particles and/or quantum dots.

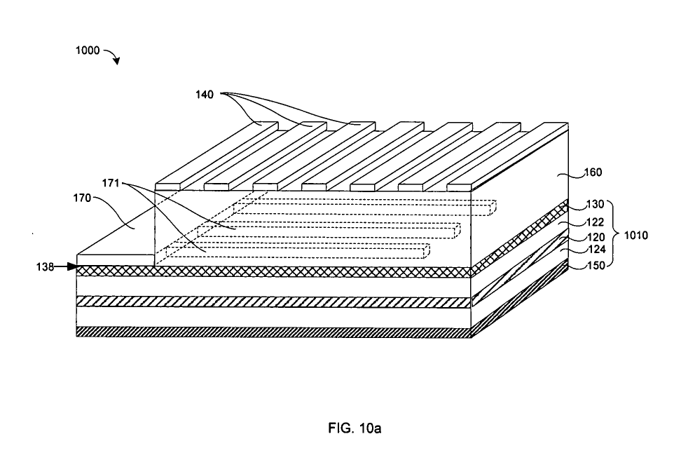

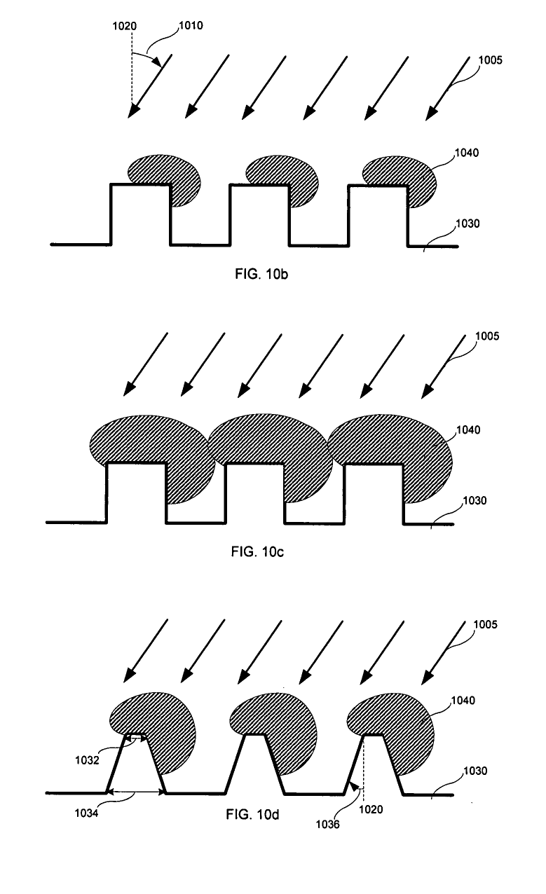

FIG. 10a illustrates a light-emitting device 1000 including a feedback element 140, such as a wire-grid polarizer, in accordance with one embodiment. The wire-grid polarizer may serve as a polarization feedback element. In some embodiments, the wire-grid polarizer may include metal (e.g., silver, aluminum) lines separated by non-conducting region, such that the wire-grid polarizer lines are electrically isolated from each other. In some embodiments, the non-conducing regions separating the reflective lines (e.g., metal lines) may include a dielectric, a semiconductor, and/or a gas or vacuum.

The wire-grid polarizer structure may have a period (e.g., width of a metal line and an adjacent gap) greater than about 50 nm (e.g., greater than about 100 nm, greater than about 150 nm, greater than about 200 nm, greater than about 300 nm). The wire-grid polarizer may have a period less than about 600 nm (e.g., less than about 500 nm, less than about 400 nm, less than about 300 nm, less than about 200 nm, less than about 150 nm, less than about 100 nm). The wire-grid polarizer reflective lines (e.g., metal lines) may have a width greater than about 30 nm (e.g., greater than about 50 nm, greater than about 75 nm, greater than about 100 nm, greater than about 150 nm). The wire-grid polarizer reflective lines (e.g., metal lines) may have a width less than about 300 nm (e.g., less than about 250 nm, less than about 200 mm, less than about 150 nm, less than about 100 nm, less than about 75 nm, less than 50 nm). The height of the reflective lines (e.g., metal lines) may be greater than or equal to about the width of the lines (e.g., greater than or equal to about 2 times the width of the lines, greater than or equal to about 3 times the width of the lines).

As described in connection with FIG. 3, a material region 160 may be disposed over emission surface 138 of a light-emitting material stack 1010 (e.g., a semiconductor light-emitting material stack). Feedback element 140 may be disposed over material region 160. In some embodiments, material region 160 may be disposed in contact with emission surface 138 and/or feedback element 140. In some embodiments, material region 160 is electrically insulating.

Light-emitting device 1000 may include a polarization manipulation region 130 (e.g., a layer having a dielectric function that varies spatially according to a pattern and/or a roughened surface), a backside reflective layer 150, an n-type (p-type) layer 122, a p-type (n-type) layer 124, and a light-generating region 120 (e.g., active region) between layer 122 and 124.

A top electrical contact 170 and electrically conductive fingers 171 may be arranged so as to electrically contact layer 122. Top contact 170 and fingers 171 can be formed of electrically conductive materials, such as metal(s) and/or conductive oxides (e.g., transparent conductive oxides), and may contact light emission surface 138 of the light-emitting material stack so as to inject current into the light-emitting material stack. Top contact 170 and metal fingers 171 may contact manipulation region 130, as in the case where the manipulation region includes a patterned and/or roughened emission surface 138. Alternatively, or additionally, a wire-grid polarizer (e.g., feedback element 140 of FIG. 10) can serve as a top electrical contact and material region 160 may include an electrically conductive region or material that can provide for electrical current injection to the emission surface 138 of the material stack.

Fingers 171 can be oriented at any angle with respect to the wire-grid polarizer reflective lines (e.g., metal lines) over region 160 (e.g., feedback element 140). For example, fingers 171 may be perpendicular or parallel to the wire-grid polarizer lines, or the fingers may be oriented at any other angle relative the wire-grid polarizer reflective lines (e.g., metal lines) (e.g., feedback element 140). Metal fingers 171 may be separated by distances and may have widths such that metal fingers 171 do not operate as a wire-grid polarizer. Alternatively, metal fingers 171 may be separated by distances and may have widths such that metal fingers 171 do operate as a wire-grid polarizer. In such a configuration, both fingers 171 and the wire-grid polarizer over region 160 (e.g., feedback element 140) may serve as polarization feedback elements.

Light-emitting device 1000 may serve as polarization recycling device wherein the wire-grid polarizer (e.g., feedback element 140) that may be disposed over the material region 160 can serve as part or all of a polarization feedback element. A patterned and/or roughened layer can serve as part or all of a polarization manipulation region 130, however it should be appreciated that the techniques presented are not limited in this respect. For example, a reflective layer 150 and/or light scattering centers dispersed within material region 160 can serve as a polarization manipulation region. Examples of light scattering centers can include particles having an index of refraction different than that of a surrounding host material. Examples can include phosphor particles, nanostructures such as quantum dots and nanowires, and metal nanoparticles such as high-index metal nanoparticles (e.g., titanium-based nanoparticles).

Light-emitting device 1000 may be fabricated by processes known to those of ordinary skill in the art. A multilayer semiconductor/metal stack including layers 170, 130, 122, 120, 124, and 150 may be formed using semiconductor fabrication processes known to those in the art. To form the wire-grid polarizer, layer 160 may be deposited on the multilayer semiconductor/metal stack and a metal (e.g., silver, aluminum) layer may be deposited thereon. The metal layer may be patterned, for example using photolithography, deep-ultraviolet photolithography, interference lithography, imprint lithography, and/or e-beam lithography to form the wire-grid polarizer 140 lines. A region of the wire-grid polarizer 140 and layer 160 over contact pad 170 may be removed (e.g., wet and/or dry etched) to expose contact pad 170 so as to enable electrical contacting of the device, for example via wire-bonding.

Alternatively, or additionally, wire-grid polarizer structures may be fabricated using angled deposition processes, as illustrated in FIGS. 10b-10d. The deposition process may include an evaporation processes, such as metal evaporation. Metal nanostructures, for example wire-grid lines of a wire-grid polarizer, may be deposited onto a patterned surface. Angled deposition can be used to facilitate the introduction of a separation between each deposited metal feature, for example between deposited metal lines.

FIG. 10b illustrates a cross-section schematic of such an angled deposition process onto a patterned surface. Patterned surface 1030 can be formed of an electrically insulating material. Patterned surface 1030 can include a dielectric (e.g., oxide, silicon oxide, silicon oxynitride, fused silica, spin-on-glass, epoxy, one or more polymers) and/or a semiconductor. Patterned surface 1030 may be formed using any suitable patterning process, for example a patterning process that can form features having dimensions of about hundreds to tens of nanometers. Examples of patterning processes include photolithography, deep-ultraviolet photolithography, interference lithography, imprint lithography, and e-beam lithography. The patterned surface may include shapes such as rectangular cross-section features (e.g., lines, such as parallel lines), as viewed in cross-section in FIG. 10b.

After forming patterned surface 1030, metal can be deposited (e.g., evaporated) with a deposition angle 1010 (represented by arrows 1005) with respect to a surface normal 1020 of patterned surface 1030. Deposition angle 1010 can be greater than about zero degrees (e.g., greater than about 10 degrees, greater than about 20 degrees, greater than about 30 degrees, greater than about 40 degrees, greater than 50 degrees, greater than about 60 degrees). Reflective features 1040 (e.g., metal lines) may form on tops and parts of the sidewalls of the surface features of patterned surface 1030. Metal may be absent in the recessed regions between the surface features of patterned surface 1030 since each feature may act as an deposition shadow mask for adjacent recessed regions.

However, as the metal features grow, adjacent metal features may contact each other during the deposition process. FIG. 10c illustrates such a situation where adjacent deposited metal features have joined together. To alleviate such effects, the cross-section shape of the surface features of patterned surface 1030 may be tapered.

FIG. 10d illustrates a cross-section schematic of such an angled deposition process onto a patterned surface having tapered features, in accordance with one embodiment. Patterned surface 1030 can have nanostructure surface features having top regions 1032 that are narrower than bottom regions 1034. Top regions 1032 can be the tops of the surface features. Bottom regions 1034 can be the bases of the surface features.

The tapered surface features can include angled sides (or portions of sides) having an angle 1036 with respect to the surface normal of greater than about 5 degrees (e.g., greater than about 10 degrees, greater than about 20 degrees, greater than about 30 degrees, greater than about 45 degrees). The tapered surface features can have triangular cross-sections, trapezoidal cross-sections, and/or rounded cross-sections. The tapered surface features can include straight sidewall bases and tapered tops. The tapered tops can include triangular cross-sections, trapezoidal cross-sections, and/or rounded cross-sections.

During metal deposition (e.g., evaporation), metal regions are deposited over at least some of the surface features, wherein the metal regions of two adjacent surface features are isolated from each other. The separation between metal regions may be facilitated by the tapered features of patterned surface 1030. The nanostructure deposited metal features may be lines, for example parallel lines. The nanostructure surface features' bottom regions may be separated by less than 75 nm and/or the nanostructure surface features' bottom regions may have widths of less than 75 nm.

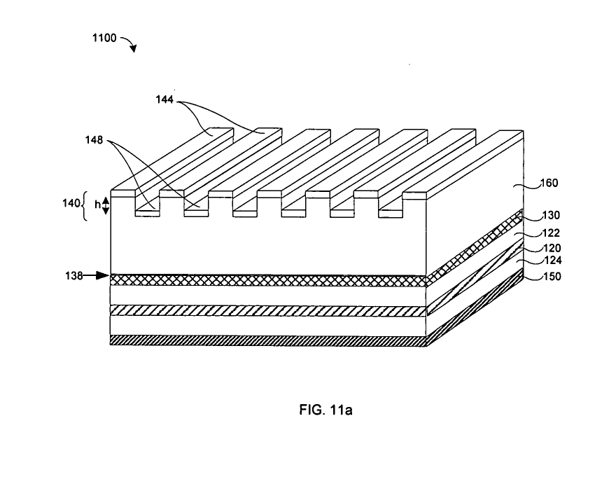

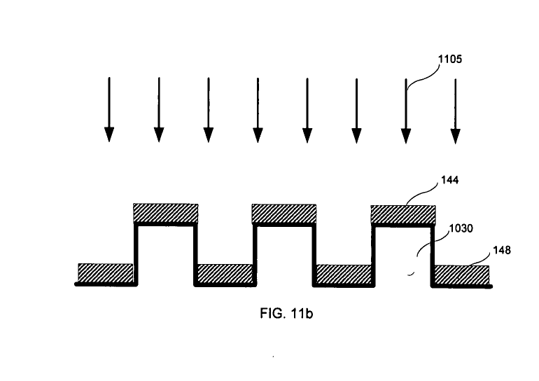

FIG. 11a illustrates a light-emitting device 1100 similar to that illustrated in FIG. 10a, except that feedback element 140 can include a multi-level polarizer structure, in accordance with one embodiment. Although not shown in FIG. 11a, top contact structures may electrically contact layer 122, as shown in FIG. 10a. The multi-level structure feedback element 140 may include a first reflective structure 144 (e.g., first metal structure) and a second reflective structure 148 (e.g., second metal structure) separated by a distance of h.

The separation distance h can be less than about 500 nm (e.g., less than about 250 nm, less than about 100 nm, less than about 80 nm, less than about 50 nm, less than about 40 nm, less than 20 nm). The separation distance h can be less than about one peak wavelength of the emitted light (e.g., less than about one half the peak wavelength, less than about one fifth the peak wavelength, less than about one sixth the peak wavelength, less than about one tenth the peak wavelength, less than about one twentieth). Such close proximity between multiple metal levels can result in a structure that interacts differently with light than multiple single-level wire-grid polarizers having levels separated by large distances (e.g., separated by much more than one wavelength of light). Multi-level wire-grid polarizer structures may possess higher extinction ratios than single-level polarizer structures or multiple single-level polarize structures.

In some embodiments, first reflective structure 144 and second reflective structure 148 may be offset laterally so as to not significantly overlap (e.g., as viewed from above). First reflective structure 144 and second reflective structure 148 may be formed of the same material(s) (e.g., the same metal(s)). First reflective structure 144 and second reflective structure 148 can include lines (e.g., parallel lines), formed of one or more materials (e.g., one or more metals and/or one or more high index materials). The dimensions of the reflective lines and the period of the structure may be selected such that the multi-level structure functions as a reflective polarizer. Typical dimensions for such reflective lines were previously presented in relation to the single-level wire-grid polarizer structure illustrated in FIG. 10a.

A multi-level structure can serve as a polarization feedback element, as previously described for a single-level wire-grid polarizer. However it should be appreciated that, in some embodiments, the multi-level structure may serve as a polarization feedback element (e.g., reflective polarizer) and/or a propagation direction feedback element. A multi-level structure, such as that illustrated in FIG. 11a, can reflect P polarized light having large propagation angles with respect to the surface normal (e.g., greater than about 30 degrees, greater than about 45 degrees, greater than about 60 degrees, greater than about 80 degrees) and transmit P polarized light having small propagation angles with respect to the surface normal (e.g., less than about 30 degrees, less than about 45 degrees, less than about 60 degrees, less than about 80 degrees). Such a multi-level structure can reflect S polarized light irrespective of propagation direction.

FIG. 11b illustrates a process that may be used to form a multi-level structure, such as the feedback element 140 of FIG. 11a, in accordance with one embodiment. The process may include forming a patterned surface 1030, as previously described in the description of FIG. 10b-d. Patterned surface 1030 may include surface features (e.g., lines, such as parallel lines) having rectangular, triangular, trapezoidal, rounded and/or semi-circular cross-sections.

After forming patterned surface 1030, metal(s) and/or high index material(s) can be deposited (e.g., evaporated) at normal incidence to form a multi-level metal structure including first reflective structures 144 and second reflective structures 148. Using normal incidence deposition, reflective material may be deposited in recessed regions between surface features of patterned surface 1030 such that first reflective structures 144 and second reflective structures 148 can be separated from each other (e.g., not connected). Although normal incidence deposition may be used to form the reflective structures, it should be appreciated that angled deposition may also form similar structures.

It should be appreciated that the reflective polarizers described herein may be used as free-standing polarizers and/or may be integrated with a device (e.g., a light-emitting device), for example, at the device and/or device package level.

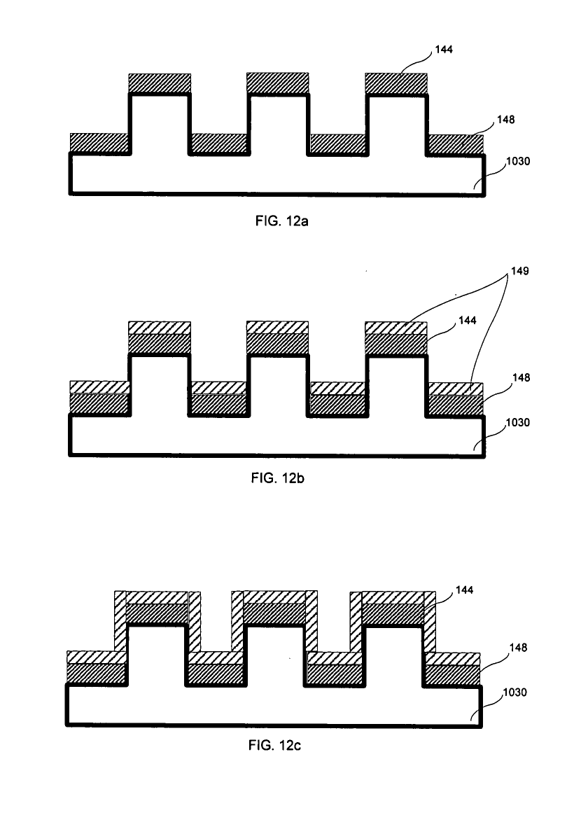

FIGS. 12a-c illustrate cross-sections of multi-level wire-grid polarizer structures that can include first reflective structures 144 and second reflective structures 148, in accordance with some embodiments. First and second reflective structures, 144 and 148, may be supported by patterned surface 1030. Patterned surface 1030 may be part of a substrate or a layer of a device and/or package of a device. As illustrated in FIG. 12b, a protective layer 149 may be deposited over reflective structures 144 and/or 148 (and may cover part or all of the metal). Protective layer 149 may prevent oxidation of the metal layers. Protective layer 149 may be formed of one more materials, such as one or more dielectric materials (e.g., oxides, such as silicon dioxide, silicon nitride, or combinations thereof) and/or one or more semiconductors. In the polarizer structure of FIG. 12b, protective layer 149 can cover the top surfaces of reflective structures 144 and/or 148. In the polarizer structure of FIG. 12c, protective layer 149 can cover the side surfaces of reflective structures 144 and/or 148.

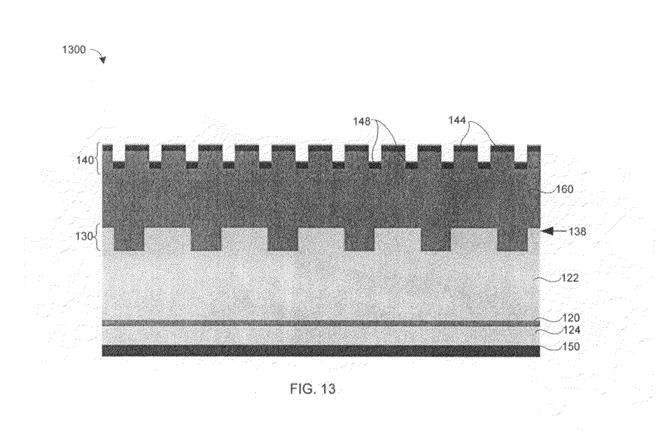

FIG. 13 illustrates a light-emitting device 1300 including a multi-level feedback element 140, in accordance with one embodiment. Feedback element 140 that may include a multi-level wire-grid polarizer disposed over (e.g., directly on) material layer 160. Light-emitting device 1300 can include a patterned surface, such as a patterned emission surface, that may serve as, part or all of, a polarization manipulation region 130.

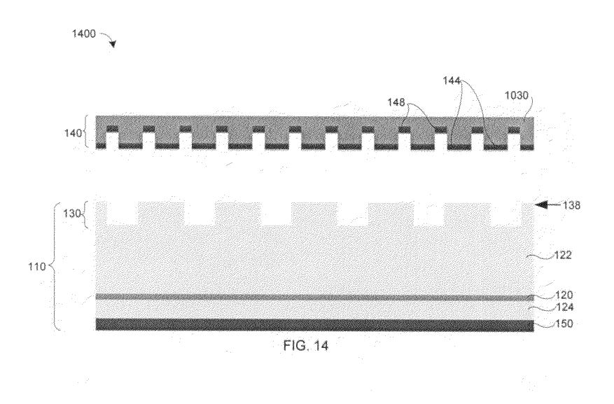

FIG. 14 illustrates a light-emitting system 1400 including a multi-level feedback element 140 disposed over a light-emitting device 110, in accordance with one embodiment. Feedback element 140 may include a multi-level polarizer formed on a substrate 1030 (e.g., a transparent substrate such as a fused silica substrate) which may serve as a window for the light-emitting system 1400. The wire-grid polarizer may be arranged such that the reflective lines (e.g., metal lines) lie between the light-emitting device 110 and substrate 1030, as illustrated in FIG. 14. Alternatively, the wire-grid polarizer may be arranged such that substrate 1030 lies between the light-emitting device 110 and the reflective lines (e.g., metal lines). A medium separating feedback element 140 and the light emission surface 138 of light-emitting device 110 may include a material and/or a gas/vacuum. In some embodiments, feedback element 140 may be of a package of light-emitting device.

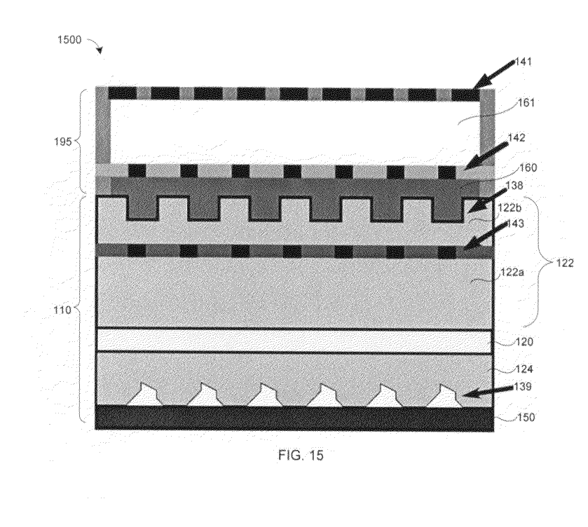

FIG. 15 illustrates a light-emitting system 1500 wherein a feedback element can include a plurality of polarizers (e.g., reflective polarizers, such as a plurality of wire-grid polarizers), in accordance with one embodiment. Light-emitting system 1500 can include a light-emitting device 110 and a package 195 for the light-emitting device 110. A plurality of polarizers may be part of the light-emitting device and/or the package of the light-emitting device. In some embodiments, the plurality of polarizers may have substantially aligned linear polarization axes. The use of a plurality of polarizers may provide for a higher extinction ratio (e.g., transmitted S polarization over transmitted P polarization) as would be achieved with only one polarizer.

One or more patterned and/or roughened region(s) may be formed on and/or within the light-emitting device, for example on and/or within layer 122 (e.g., semiconductor n or p layer), layer 120 (e.g., active region), and/or layer 124 (e.g., semiconductor p or n layer) of light-emitting device 110. Light-emitting device 110 may include one or more patterned and/or roughened regions that may serve as polarization manipulation regions. For example, light-emitting device 110 can include a patterned and/or roughened emission surface 138. Alternatively, or additionally, the light-emitting device 110 can include a patterned and/or roughened backside surface 139.

One or more polarizers (e.g., polarizers 141 and/or 142) may be part of package 195 of light-emitting device 110. Polarizer 141 may be disposed over a top-side, a bottom-side, and/or within a window (not shown) of the package, where light emitted by the light-emitting device may be transmitted through the window. Polarizer 142 may also be integrated as part of package 195. For example, polarizer 141 may be disposed on a top-side of the package window and polarizer 142 may be disposed on a bottom-side of the package window.

One or more polarizers (e.g., polarizers 143 and/or 142) may be integrated on and/or within light-emitting device 110. Polarizer 142 may be integrated with the light-emitting device 110 by formation on a material layer 160 on the device 110, as previously discussed. Embedded polarizer 143 can be formed on a semiconductor layer 122a and then deposition (e.g., epitaxial growth) can be used to grow a semiconductor layer 122b through the gaps in the reflective lines (e.g., metal lines) of polarizer 143.

Regions 160 and 161 can include one or more material regions and/or gas/vacuum regions, and can posses any suitable refractive index. The refractive indices of regions 160 and 161 may be substantially similar. Alternatively, the refractive index of region 161 can be less than the refractive index of region 160. Alternatively, the refractive index of region 161 can be greater than the refractive index of region 161.

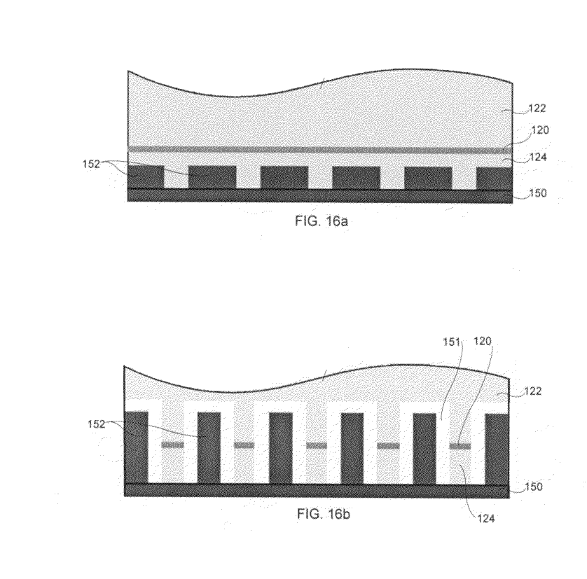

FIGS. 16a-b illustrate light-emitting devices including polarizer structures 152 located in close proximity to the active region, in accordance with one embodiment. The polarizer structures may be wire-grid polarizers structures, may be formed of one or more metals and/or one or more high index materials, and may have dimensions similar to those previously described for wire-grid polarizers. In some embodiments, a polarizer 152 having a wire-grid structure may be disposed under and/or through an active region 120. In some embodiments, polarizer 152 may be disposed on a backside reflective layer 150, as illustrated in FIGS. 16a and 16b. Alternatively, or additionally, the polarizer structure may be disposed on the emission surface and/or within the top layer 122 of the light-emitting device.

When polarizer 152 is in close proximity (e.g., less than about 10 nm apart, less than about 25 nm apart, less than about 50 nm apart, less than about 100 nm apart) with the active region 120, the rate of spontaneous emission of S and P polarization states may be altered. The rate of spontaneous emission for P polarized light may be larger than the rate of spontaneous emission for S polarized light. The percentage of light emitted having P polarization can therefore be larger than the percentage of light emitted having S polarization. In some embodiments, the rate of spontaneous emission of P polarized light may be greater than about 2 times (e.g., greater than about 3 times, greater than about 4 times, greater than about 5 times, greater than about 10 times) the rate of spontaneous emission of S polarized light. In some embodiments, the polarizer disposed in close proximity to the active region influences the generation of light by the active region such that that a majority (e.g., greater than about 50%, greater than about 60%, greater than about 65%, greater than about 70%, greater than about 80%, greater than about 90%) of the generated light has a first polarization (e.g., a particular linear polarization). A minority of the generated light may have a second polarization orthogonal to the first polarization.

FIG. 16a illustrates a lower portion of a material stack (e.g., semiconductor material stack) of a light-emitting device having a polarizer 152 disposed therein, in accordance with one embodiment. Polarizer 152 may be in contact with the backside reflective layer 150. Polarizer 152 and reflective layer 150 may be formed of the same or different metal(s). In some embodiments, the polarizer includes a wire-grid polarizer structure. Polarizer 152 may be in close proximity (e.g., less than about 10 nm apart, less than about 25 nm apart, less than about 50 nm apart, less than about 100 nm apart) with the active region 120.

FIG. 16b illustrates a lower portion of a material stack (e.g., semiconductor material stack) of a light-emitting device including a polarizer structure that intersects portions of active region 120, in accordance with one embodiment. A dielectric layer 151 (e.g., oxide, silicon oxide, silicon nitride, silicon oxynitride) may separate the active regions 120 from the reflective lines (e.g., metal lines) of polarizer 152 and thus dielectric layer 151 may electrically insulate the active region from the polarizer. The width of semiconductor regions between the polarizer 152 reflective lines (e.g., metal lines) may be less than about 200 nm (e.g., less than about 100 nm, less than about 50 nm, less than about 30 nm). The thickness of the dielectric layer 151 may be less than about 30 nm (e.g., less than about 20 nm, less than about 10 nm, less than about 5 nm). The height of the polarizer regions 150 may be greater than about 30 nm (e.g., greater than about 50 nm, greater than about 100 nm, greater than about 200 nm). The width of the polarizer regions 152 may be similar to those previously described for wire-grid polarizers.

The illustrated structures of FIGS. 16a-b show embodiments where the polarizer structures may be embedded within the light-emitting material stack (e.g., semiconductor material stack). The polarizer structures may be in close proximately to the active region so as to alter the rate of spontaneous emission of S and P polarization. Alternatively, or additionally, the rate of spontaneous emission of S and P polarization may be altered by placing a wire-grid polarizer in close proximity over (e.g., over a light emission surface) and/or partially embedded within the active region.

FIG. 17 is a graph of calculation results of a polarization recycling light-emitting devices, such as the device structure illustrated in FIG. 10a, in accordance with one embodiment. The results are obtained using a finite difference time domain computer calculation solving Maxwell's equations for the device structure. The calculations used a wavelength light emission of 520 nm from the active region of the light-emitting device. The active region was assumed to emit equal amounts of S and P polarized light. The material stack was a GaN/InGaN LED semiconductor stack having InGaN quantum wells in the active region. The light emission surface of the semiconductor stack included regions with a hexagonal pattern of holes and regions with a flat semiconductor surface. An aluminum wire-grid polarizer was located over the semiconductor light emission surface and separated by a medium having a refractive index that was varied as a parameter. The separation distance between the semiconductor light emission surface and the polarizer was 1 micron, wherein the separation distance refers to the minimum separation distance between the wire-grid polarizer and the semiconductor light emission surface (e.g., distance between the topmost portion of the surface and the bottom-most portion of the wire-grid polarizer). The wire-grid polarizer period was 110 nm, and the width and height of the polarizer reflective lines (e.g., metal lines) was 55 nm and 100 nm, respectively.

A normalized P polarized light emission transmitted through the polarizer was calculated. A polarization recycling efficiency (e.g., the percent of S polarized light that is converted to P polarized light) for the structure was then computed by accounting for the efficiency of the wire-grid polarizer calculated (via simulation) to be about 90%, corresponding to a loss of about 10% due to the wire-grid polarizer. The polarization recycling efficiency is estimated as the fraction of total light emission that is P polarized including recycling minus the fraction of total light emission that is P polarized with no recycling, divided by the fraction of total light emission that is P polarized with no recycling. The fraction of total light emission that is P polarized with no recycling is estimated as the fraction of P polarized light emitted by device without a polarizer (0.5) minus the loss due to the polarizer (about 10%/2=0.05). Polarization recycling efficiencies of greater than about 20% (e.g., greater than about 30%, greater than about 40%, greater than about 50%) are considered substantial.

The calculation results shown in FIG. 17 illustrate the polarization recycling efficiency as a function of the refractive index of the medium separating the polarizer and the light emission surface of the GaN-based semiconductor light-emitting material stack. A GaN-based light-emitting material stack can include layers (e.g., including an active region) formed of one or more layers of AlₓIn_{y}Ga_{z}N (wherein x+y+z=1), for example GaN, InGaN, AlGaN, or combinations thereof. The calculation results show an unexpected result that there exists a critical range of refractive indices of the separation medium for which polarization recycling occurs. Based on the calculation results, it is thus appreciated that separation medium refractive indices of less than about 1.8 (e.g., less than about 1.6, less than about 1.5, less than about 1.4, less than about 1.3) result in polarization recycling. Since the simulated GaN-based LED semiconductor stack (e.g., having a GaN emission surface) has a refractive index of about 2.4, converting the critical range results in terms of the refractive index of the semiconductor emission surface results in the conclusion that a separation medium refractive index of less than about 0.8 times (e.g., less than about 0.75, less than about 0.7, less than about 0.65, less than about 0.6, less than about 0.5) the refractive index of the emission surface of the semiconductor stack can provide for polarization recycling.

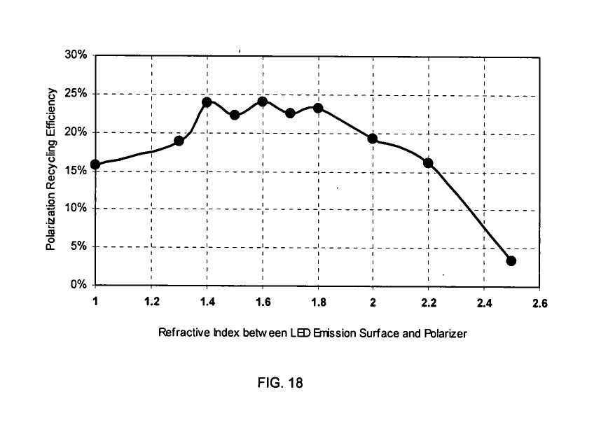

FIG. 18 is a graph of calculation results of polarization recycling light-emitting devices, such as the device structure illustrated in FIG. 10a, in accordance with one embodiment. The results are obtained using a finite difference time domain computer calculation solving Maxwell's equations for the device structure. The calculations used a wavelength light emission of 625 nm from the active region of the light-emitting device. The active region was assumed to emit equal amounts of S and P polarized light. The material stack was an AlInGaP-based LED semiconductor stack having AlInGaP-based quantum wells in the active region. The light emission surface of the semiconductor stack included a patterned surface with holes arranged in a quasi-crystalline pattern. Other structural parameters were the same as for the calculations done to obtain the results of FIG. 17.

The calculation results shown in FIG. 18 illustrate the polarization recycling efficiency as a function of the refractive index of the medium separating the polarizer and the light emission surface of an AlInGaP-based semiconductor light-emitting material stack. An AlInGaP-based light-emitting material stack can include layers (e.g., including an active region) formed of one or more layers of AlₓIn_{y}Ga_{z}P (wherein x+y+z=1), for example GaP, InGaP, AlInP, or combinations thereof. The calculation results show an unexpected result that there exists a critical range of refractive indices of the separation medium for which polarization recycling occurs. Based on the calculation results, it is thus appreciated that separation medium refractive indices of less than about 2.6 (e.g., less than about 2.4, less than about 2.2, less than about 2.0, less than about 1.8, less than about 1.6, less than about 1.5, less than about 1.4, less than about 1.3) result in polarization recycling. Since the simulated AlInGaP-based LED semiconductor stack (e.g., having an (Al_{0.6}Ga_{0.4})_{0.5}In_{0.5}P emission surface) has a refractive index of about 3.3, converting the critical range results in terms of the refractive index of the semiconductor emission surface results in the conclusion that a separation medium refractive index of less than about 0.8 times (e.g., less than about 0.75, less than about 0.7, less than about 0.65, less than about 0.6, less than about 0.5) the refractive index of the emission surface of the semiconductor stack can provide for polarization recycling.

FIG. 19 is a graph of calculation results of polarization recycling light-emitting devices, such as the device structure illustrated in FIG. 10a, in accordance with one embodiment. The results are obtained using a frequency domain computer calculation solving Maxwell's equations for the device structure. The calculations used a wavelength light emission of 520 nm from the active region of the light-emitting device. The active region was assumed to emit equal amounts of S and P polarized light. The material stack was a GaN/InGaN LED semiconductor stack having InGaN quantum wells in the active region. The light emission surface of the semiconductor stack included a hexagonal pattern of holes. A silver wire-grid polarizer was located over the semiconductor light emission surface and separated by a medium having a refractive index of one (e.g., one or more gases, vacuum). The separation distance between the semiconductor light emission surface and the polarizer was varied as a simulation parameter. The wire-grid polarizer period was 160 nm, and the width and height of the polarizer reflective lines (e.g., metal lines) was 80 nm and 150 nm, respectively.

The calculation results shown in FIG. 19 illustrate the polarization recycling efficiency as a function of the separation distance between the polarizer and the light emission surface of the GaN/InGaN semiconductor stack. The calculation results show an unexpected result that there exists a critical range of separation distances for which a substantial amount (e.g., a majority, for example greater than about 50%, greater than about 60%, greater than about 70%) of light (e.g., S polarized light) undergoes polarization recycling and is emitted by the overall structure. Based on the calculation results, it is thus appreciated that separation distances of less than about 2.5 microns (e.g., less than about 2.0 microns) and/or greater than about 0.5 microns (e.g., greater than about 0.75 microns, greater than about 1.0 microns, greater than about 1.5 microns) result in substantial polarization recycling. Expressed in terms of the light wavelength, substantial polarization recycling may occur for separation distances less than about 5 times the peak wavelength of emitted light (e.g., less than about 4 times the peak wavelength of emitted light) and/or greater than about one peak wavelength (e.g., greater than about 1.5 times, greater than about 2 times, greater than about 3 times the peak wavelength of emitted light).

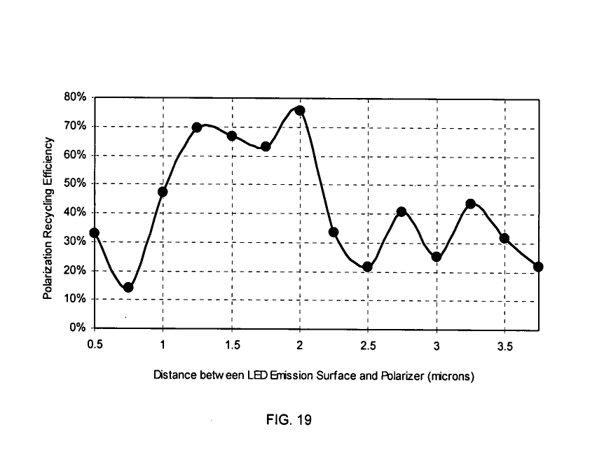

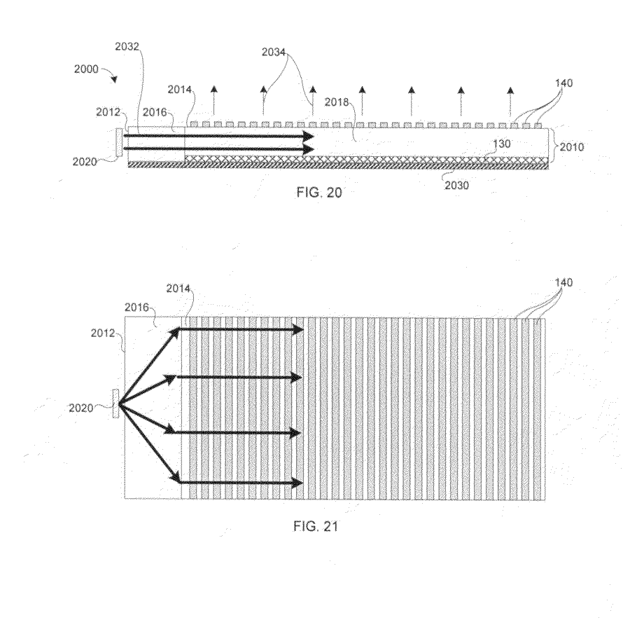

FIGS. 20 and 21 are side and top views of a polarization recycling light-emitting assembly 2000, in accordance with one embodiment. The polarization recycling light-emitting assembly may be an illumination system that can serve as a sub-system in an optical system. In some embodiments, the polarization recycling light-emitting assembly may be a display backlight unit, for example a liquid crystal display (LCD) backlight unit. Examples of display backlighting systems are provided, for example in, U.S. Patent Publication No. 20070045640, entitled “Light emitting devices for liquid crystal displays,” filed on Aug. 23, 2005, U.S. Patent Publication No. 20060043391, entitled “Light emitting devices for liquid crystal displays,” filed on Aug. 23, 2005, U.S. Patent Publication No. 20070085082, entitled “Light-emitting devices and related systems,” filed on Dec. 30, 2005, U.S. patent application Ser. No. 11/413,968, entitled “LCD thermal management methods and systems,” filed on Apr. 28, 2006, and U.S. patent application Ser. No. 11/429,649, entitled “Liquid crystal display systems including LEDs,” filed on May 5, 2006, which are herein incorporated by reference in their entirety.

A polarization recycling light-emitting assembly may include an illumination component having at least one light input surface and at least one light emission surface. The Illumination component may have any shape, including a rectangular shape (e.g., a rectangular panel), a cylindrical shape (e.g., a rod shape), a circular or semi-circular shape, or an oval or semi-oval shape. A light source (e.g., one or more solid state light sources, such as one or more LEDs, one or more laser diodes) may be configured to emit at least some light into the light input surface of the illumination component. A polarizer (e.g., wire-grid polarizer) may be configured to receive at least some light emitted via the light emission surface of the illumination component. The polarizer may be disposed over (e.g., directly on) the light emission surface of the illumination component and can allow for polarization recycling within the illumination component. In some embodiments, the light-emitting assembly may include a polarization manipulation region configured to scramble the polarization of light impinging thereon. The polarization manipulation region may include a dielectric function that varies spatially according to a pattern. To provide for effective scrambling of the polarization, the pattern may be a two-dimensional pattern that varies spatially along at least two dimensions.

In some embodiments, the illumination component includes a lightguide panel 2010 (e.g., a rectangular panel). Panel 2010 may be formed of an optically transparent material (e.g., glass, polymer, such as PMMA). Panel 2010 may include at least one light input surface that can include an edge 2012 of the panel. Panel 2010 may also include at least one light emission surface that comprises a face 2014 of the panel. Light source 2020 may be configured to emit light into edge 2012 of panel 2010. Light source 2020 may include one or more light sources. Light source 2020 may include a solid-state light-emitting device, including but not limited to, one or more LEDs and/or laser diodes. Alternatively, or additionally, one or more light sources may emit light into a backside face of the panel.

Panel 2010 may include homogenization region 2016 that allows light coupled into edge 2012 to be spatially homogenized so as to have a substantially uniformly intensity distribution across the width of the panel. Panel 2010 may include a light scattering region 2018 that can include light scattering features (e.g., index variations and/or surface features) that can scatter light propagating along the length of the panel (represented by arrows 2032) into other directions, where part of that scattered light may be directed out via emission face 2014 (represented by arrows 2034) of the panel 2010. The density of the light scattering features can vary along the length of the panel, such that the amount of light that escapes via face 2014 is uniform along the length of panel 2010.

Panel 2010 may include a polarization manipulation region 130 that can alter the polarization of light impinging thereon. Polarization manipulation region 130 may include one or more patterned layers (e.g., non-periodic and/or periodic patterns), one or more roughened layers, one more diffuse and/or specular reflectors, and/or one or more phase retarders or shifters. Polarization manipulation region 130 may be disposed within, on the front emission face, and/or on the backside face of light scattering region 2018 of panel 2010. Alternatively, or additionally, polarization manipulation region 130 may be separate from the panel 2010, and for example, may be disposed under the backside face of panel 2010. A reflective layer 2030 (e.g., metal layer) may be disposed under (e.g., directly in contact with) the backside face of the panel 2010. In some embodiments, reflective layer 2030 is a diffuse reflector and may serve as a polarization manipulation region.

Panel 2010 may include a wavelength conversion material (e.g., phosphor and/or quantum dots), for example dispersed within light scattering region 2018 and/or homogenization region 2016. In some embodiments, the wavelength conversion material can convert ultraviolet and/or blue light (e.g., generated by light source 2020, such as an LED and/or laser diode) to longer wavelengths (e.g., red, green, blue, and/or white light).

Polarizer 140 (e.g., wire-grid polarizer) may be configured to receive at least some light emitted via light emission face 2014 of panel 2010. Polarizer 140 may be disposed over (e.g., directly on, and may be integrated with the panel) the light emission face 2014 of panel 2010. Alternatively, or additionally, polarizer 140 may be disposed within the panel 2010. When polarizer 140 includes a wire-grid polarizer, the reflective lines (e.g., metal lines) of the wire-grid polarizer may be aligned perpendicular to a direction of desired polarization for light outputted from the panel emission face 2014. For example, in the illustration shown in FIGS. 20 and 21, the reflective lines (e.g., metal lines) of the wire-grid polarizer are aligned parallel to the width of the panel 2010, such that light 2034 emitted from the panel has an electric field that is perpendicular to the width of panel 2010 (parallel to the length of the panel). In some embodiments, the reflective lines (e.g., metal lines) may be aligned parallel to the length of panel 2010, such that light 2034 emitted from the panel has an electric field that is perpendicular to the length of the panel 2010 (parallel to the width of the panel). In some embodiments, the reflective lines (e.g., metal lines) may be aligned at an angle (e.g., at about 30 degrees, at about 45 degrees, at about 60 degrees) with respect to the length of the panel 2010.

During operation of light-emitting assembly 2000, polarization recycling may occur within panel 2010. Light within the panel 2010 having polarization states that are transmitted by polarizer 140 may be transmitted (arrows 2034) out of panel 2010. Light within the panel having polarization states that is returned back (e.g., reflected) by polarizer 140 may then undergo a modification of its polarization. For example, the polarization of at least part of the light that is returned back (e.g., reflected) may be altered by polarization manipulation region 130. Such a system can allow for polarization recycling at the assembly or component level. Such an assembly can allow for polarization recycling or recovery for a LCD backlight unit. It should be appreciated that a backlight unit may include a plurality of such assemblies located adjacent to each other.

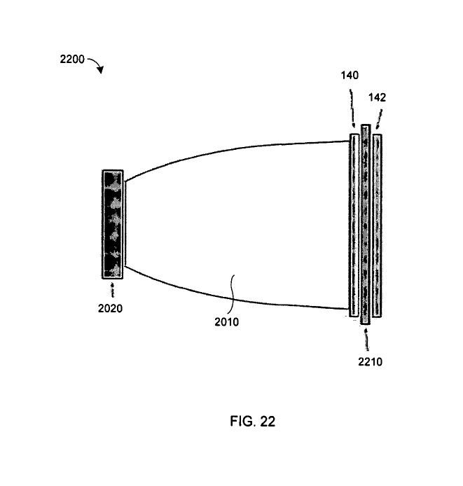

FIG. 22 is a schematic drawing of a polarization recycling liquid crystal display 2200. Such a system can allow for polarization recycling in a transmissive LCD system. In the illustrative system of FIG. 22, a light source 2020 (e.g., one or more LEDs and/or laser diodes) can emit light into a collection optic that may serve as an illumination component 2010 for transmissive LCD panel 2210. The collection optic may be shaped so as to collect and guide the light beam using total-internal reflection to bring the beam angle into the acceptance angle of the transmissive LCD panel 2210. In this manner, the illumination component can serve as a non-imaging optic with can possess light collimation properties.

A first wire-grid polarizer 140 may be located over (e.g., directly on) the light emission surface of the illumination component 2010. The first wire-grid polarizer 140 can transmit one polarization and reflect the other perpendicular polarization back towards the light emission surface of the illumination component 2010. LCD panel 2210 may be disposed after the first polarizer 140 and can rotate the polarization direction for light passing through pixel regions to be turned on (or in some systems, rotate the polarization direction for light passing through pixel regions to be turned off). On the other side of the LCD panel 2210 may be disposed a second wire-grid polarizer 142 configured to reflect the light that passed through the pixels that are off and transmit light that passed through the pixels that are on (e.g., wire-grid polarizer 142 can have a polarization direction perpendicular to the first polarizer 140). This light can reverse path through LCD panel 2210 and through first polarizer 140 and can be polarization recycled (e.g., within the illumination component, light source, and/or other parts of the system).

System 2200 can provide for increased efficiency due to recycling of light prior to emission by the illumination component and/or recycling of light that is transmitted through off pixel regions of the LCD panel. For example, if only 50% of the pixels are in the on position, the off-pixel light gets reflected and is recycled so that more light is available for distribution to the on-pixels. It should be appreciated that in the assembly and system embodiments described above, wire-grid polarizers may be fabricated using methods similar to those previously described herein.

Although the devices, assemblies, and systems presented so far have dealt mainly with polarization light recycling, it should be appreciated that light recycling can be performed based on one or more other properties of light, in addition to, or alternatively to polarization light recycling. One such feedback system is discussed below in reference to “spatial recycling,” which refers to recycling of light based at least in part on the propagation direction of the light (e.g., emitted by the light-emitting device).

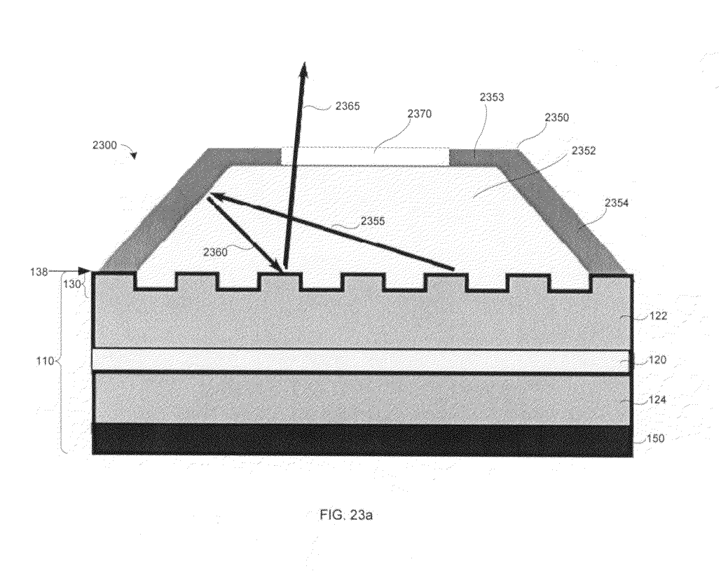

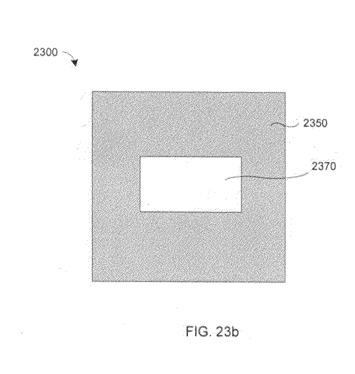

As shown in FIG. 23a, a light-emitting system 2300 may include a light generating region 120 of a light-emitting device 110. Light generating region 120 can be an active region that may be disposed between an n-type (or p-type) region 122 and a p-type (or n-type) region 124. For example, light generating region 120 may support the p-type region and the n-type region may be located over the light generating region.

Light-emitting system 2300 may include a feedback element 2350 which can be configured to transmit at least some light 2365 (of light 2355 from the light-emitting device 110) having a first range of propagation directions. The feedback element 2350 can be further configured to return back (e.g., reflect) at least some light 2360 having a second range of propagation directions, wherein the second range is not part of the first range. Feedback element 2350 can include a cavity within which light can be reflected by the cavity walls. In some embodiments, the cavity walls include reflective portions, for example some or all of the cavity walls may be coated with specular and/or diffuse reflective material. Feedback element 2350 may include a cavity region 2352 which may comprise vacuum, one or more gases (e.g., air, nitrogen, noble gas), and/or one or more materials. In some embodiments, cavity region 2352 may include or more wavelength converting materials (e.g., phosphor and/or quantum dots). Feedback element 2350 may include one or more apertures or transmissive regions 2370 (e.g., a transparent window) which can allow light propagating with a range of propagation directions to exit the light-emitting system.

One or more apertures or transmission regions may be located on a top portion 2353 of the cavity walls and/or one or more side portions 2354 of the cavity walls. When one or more apertures or transmissive regions are located on the top portion 2353 of the cavity walls, light emitted by the system 2300 may be more collimated along the normal of the emission surface 138 than in the absence of the cavity. When one or more apertures or transmissive regions are located on one or more side portions 2354 of the cavity walls, light emitted by the system 2300 may be more collimated along non-normal directions (e.g., greater than about 30 degrees, greater than about 45 degrees, greater than about 60 degrees) with respect to the normal of the emission surface 138 than in the absence of the cavity.

Light-emitting system may include a light propagation direction manipulation region 130, also referred to as a spatial manipulation region, which can be configured to alter the propagation direction of at least some of the returned light 2360 to be in the first range of propagation directions that is transmitted by feedback element 2350. Propagation direction manipulation region 130 can include a patterned region or layer having a dielectric function that varies spatially according to a pattern. Such a system can enhance the light output in a particular range of propagation directions. Such a system can be configured to increase the collimation of the light emitted by the system 2300, as compared to the light emitted by light-emitting device 110.

In some embodiments, other types of feedback elements (e.g., polarization feedback element such as a reflective polarizer, wavelength feedback element such as a wavelength filter) may be combined with a propagation direction feedback element. For example, a polarization feedback element (e.g., a reflective polarizer, such as a wire-grid polarizer) and/or a wavelength feedback element (e.g., a wavelength filter) may be disposed over the aperture 2370 of the propagation direction feedback element 2350.

In some embodiments, a wavelength filter may be disposed between the emission surface 138 of the light-emitting device and the cavity. For example, when the cavity includes a wavelength converting material, a wavelength filter may be located over the emission surface 138 and configured to allow light generated and emitted by device 110 to pass through. The wavelength filter may be configured such that light within the cavity that is wavelength converted (e.g., down-converted or up-converted) in the cavity is reflected by the wavelength filter and cannot re-enter the device.

FIG. 23b is a top view of an example of feedback element 2350 of light-emitting system 2300. As noted above, feedback element 2350 may include an aperture or transmissive region 2370. Aperture 2370 may comprise an optically transparent layer (e.g., glass, fused silica). Aperture 2370 may have an area that is smaller than the emission area of the light-emitting device 110. Aperture 2370 may be configured to lie parallel to the emission surface of the light-emitting device 110 (as shown in FIG. 23a) or may lie at any other angle with respect to the emission surface of the light-emitting device 110 (e.g., perpendicular, at 45 degrees).

In some embodiments, aperture 2370 may have a symmetric shape (e.g., square, hexagonal, circular). In some embodiments, aperture 2370 may have an asymmetric shape (e.g., rectangular, elliptical), such that light that passes through the aperture can be collimated differently along different directions.

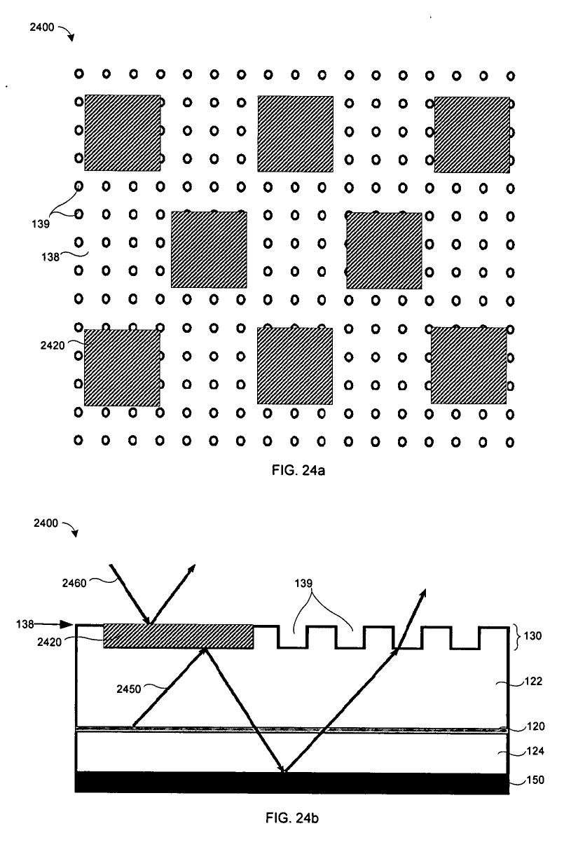

FIG. 24a depicts a schematic drawing of a top view of a light-emitting device 2400 having a plurality of reflective regions 2420 disposed on an emission surface 138. Reflective regions 2420 can be specular and/or diffuse reflectors, and may be formed of any suitably reflective (e.g., partially or completely reflective) materials, including metal(s), dielectric(s), and/or semiconductor(s). For example, both the top surface and bottom surface of reflective regions 2420 can be specular or diffuse reflectors. Alternatively, one surface of reflective region 2420 may be a diffuse reflector and the other surface may be a specular reflector. For example, the top surface may be a diffuse reflector and the bottom surface may be a specular reflector (or vice versa). In some embodiments, reflective regions 2420 are flat regions of layer 122 (e.g., semiconductor layer 122).

Emission surface 138 can be a layer of semiconductor material having a dielectric function that varies spatially according to a pattern. For example, the emission surface 138 can include a pattern of holes 139. In some embodiments, reflective regions 2420 can be arranged in a pattern. The pattern formed by reflective regions 2420 may have a larger spacing between features that the spacing between holes 139. Examples of possible patterns formed by the reflective regions are described in U.S. Patent Publication No. 20060204865, entitled “Patterned light-emitting devices,” filed Nov. 10, 2005, which is herein incorporated by reference in its entirety. The emission surface, which can include the reflective portions, may form a manipulation region of a feedback region, as described herein.

FIG. 24b is a schematic drawing illustrating a cross-sectional view of light-emitting device 2400. As shown in FIG. 24b, light can be generated by the light-generating region 120, and may be emitted with a propagation direction directed towards the emission surface 138, represented by arrow 2450. As light 2450 propagates towards emission surface 138, the light may contact the reflective region 2420 and be reflected back towards the light generating region. Eventually, the light can escape the light-emitting device and be emitted through emission surface 138.

Light-emitting device 2400 may be an element in a light-emitting system that may also include a feedback element that returns (e.g., reflects) a portion of the emitted light back towards the light-emitting device emission surface. As shown in FIG. 24b, light 2460 can be returned back (e.g., reflected) from a feedback element (not shown) and reflected off of reflective region 2420 thus enhancing the system emission by preventing the light from re-entering the light-emitting device and possibly being absorbed within light-generating region 120 (e.g., the active region).

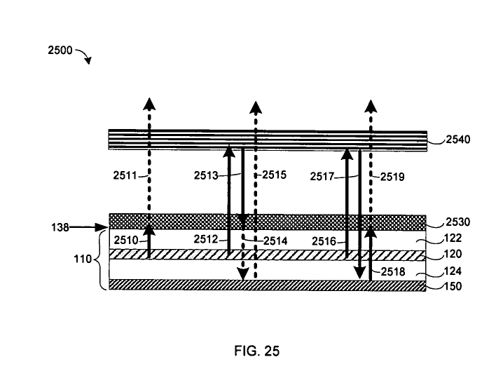

FIG. 25 is a cross-section of a light-emitting system 2500 that can enable light wavelength recycling. Light-emitting system 2500 can include a light-emitting device 110 comprising a light-generating region 120 (e.g., active region). N-type (or p-type) layer 122 may be disposed over light-generating region 120, and P-type (or n-type) layer 124 may be disposed under the light-generating region 120. Emission surface 138 of the material stack (including layer 122, 120, and 124) may be patterned and/or roughened, as previously described.

A wavelength manipulation region 2530 may be disposed over the emission surface 128 of the light-emitting material stack. Wavelength manipulation region 2530 may be located directly on emission surface 138 and/or may be separated from emission surface 138. Wavelength manipulation region 2530 may be arranged such that light emitted by the light-emitting material stack impinges on the wavelength manipulation region.

Wavelength manipulation region 2530 may include one or more wavelength converting materials, such as one more types of phosphors and/or one or more types of quantum dots. Wavelength manipulation region 2530 can convert a first range of light wavelengths to a second range of light wavelength. In some embodiments, the wavelength manipulation region can down-convert light from a higher energy (shorter wavelength) to lower energy (longer wavelength). For example, the wavelength manipulation region can down-covert blue and/or ultra-violet light to longer wavelength light (e.g., blue, green, yellow, and/or red light). In some embodiments, the light-generating region can generate and emit blue and/or ultraviolet light which may be down-converted by the wavelength manipulation region 2530.

A wavelength feedback element 2540 may be disposed over wavelength manipulation region 2530. In some embodiments, wavelength feedback element 2540 may be located prior to the output of light-emitting system 2500. The wavelength feedback element 2540 may be configured to receive light after interaction with wavelength manipulation region 2530. Alternatively, or additionally, part or all of the light emitted by via emission surface 138 may first impinge on wavelength feedback element 2540.

Wavelength feedback element 2540 may include a wavelength filter, such as a low-pass wavelength filter, a high-pass wavelength filter, and/or a band-pass wavelength filter. Wavelength feedback element 2540 may include a dielectric and/or semiconductor stack, for example a Bragg reflector or a dichroic mirror. In some embodiments, the wavelength feedback element 2540 may include an omni-directional mirror. Examples of omni-directional mirrors are described in, for example, U.S. Pat. No. 6,624,945, entitled “Thin film filters using omnidirectional reflectors,” filed on Feb. 12, 2001, which is herein incorporated by reference in its entirety.

During operation, system 2500 may enable wavelength recycling such that the light outputted by the system has a range of wavelengths that are transmitted by wavelength feedback element 2540. For example, wavelength feedback element 2540 may transmit light having one or more colors (e.g., red, green, blue, cyan, yellow, and/or visible light excluding ultraviolet light). Light not having wavelengths in the range of wavelengths transmitted by wavelength feedback element 2540 may be reflected back towards wavelength manipulation region 2530 and may undergo conversion to a wavelength of light that can be transmitted by the wavelength feedback element 2540.

For example, ultraviolet and/or blue light may be generated by light generating region 120 and may be down-converted to one or more longer wavelengths, such as one or more wavelengths in the visible regime (e.g., wavelengths greater that blue and/or ultraviolet wavelengths). Wavelength feedback element 2540 can be configured to return back (e.g., reflect) light having ultraviolet and/or blue wavelengths, and output (e.g., transmit) light having wavelengths longer than ultraviolet and/or blue light. In the case of ultraviolet generated light, such wavelength recycling can allow substantially all of the ultraviolet light to be converted to visible light before emission by the system. Such a system may be beneficial in that ultraviolet light may be completely (or almost completely) converted to visible light before emission by the system, thereby reducing or eliminating the danger of exposure to ultraviolet light.

Examples of possible light generation and emission cases are illustrated in FIG. 25. In one case, light 2510 may be generated by light generating region 120 and may have a wavelength in a first range of wavelengths (depicted by a solid arrow), for example blue and/or ultraviolet light. Light 2510 may be transmitted into wavelength manipulation region 2530 and may undergo conversion (e.g., down-conversion or up-conversion) to light 2511 having a wavelength (represented by a dashed arrow) that is transmitted by wavelength feedback element 2540.

In another case, light 2512 may not be converted to another wavelength after transmitting through wavelength manipulation region 2530 on a first pass. Light 2512 may impinge on wavelength feedback element 2540 and may be returned back (e.g., reflected back), as represented by arrow 2513. Light 2513 may then be wavelength converted to light 2514. Light 2514 may have a propagation direction such that the light is transmitted back into light-emitting device 110 structure and may be reflected (arrow 2515) by reflective layer 150. Light 2515 may then be outputted (e.g., transmitted) by wavelength feedback element 2540.

In another case, light 2516 may not be converted to another wavelength after transmitting through wavelength manipulation region 2530 on a first pass or second pass. Light 2516 may impinge on wavelength feedback element 2540 and may be returned back (e.g., reflected back), as represented by arrow 2517. Light 2517 may be transmitted back into the light-emitting device 110 structure and may be reflected (arrow 2514) by reflective layer 150. Light 2514 may impinge wavelength manipulation region 2530 and may undergo wavelength conversion (arrow 2515). That light may then be outputted (e.g., transmitted) by wavelength feedback element 2540. More generally, light may undergo wavelength conversion after any number of passes (e.g., three, four, five, etc.).

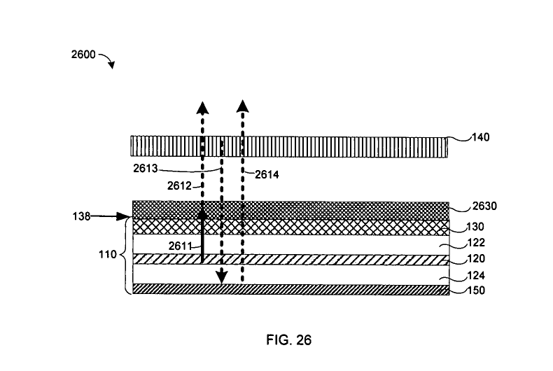

FIG. 26 is a cross-section of a light-emitting system 2600 that can include a wavelength conversion region 2630. Wavelength conversion region(s) can be used to alter the wavelength of light. The converted light may impinge onto a feedback element, where some or all of the light having one or more desired properties (e.g., polarization, propagation direction, and/or wavelength) may be emitted out of the device. In one embodiment, the feedback element includes one or more polarization feedback element (e.g., a reflective polarizer such as a wire-grid polarizer). In one embodiment, the feedback element includes one or more propagation direction feedback elements (e.g., a reflective cavity with an opening, one or more prisms, an array of micro-prisms). In one embodiment, the feedback element includes one or more wavelength filters (e.g., a dichoric filter, a dielectric stack, a semiconductor stack, etc.). The wavelength conversion region 2630 and/or the feedback element 140 may be supported by the light-emitting material stack, for example a light-emitting die (e.g., a light-emitting semiconductor die). For example the wavelength conversion region 2630 may be supported by (e.g., directly on) the light emission surface 138 of the light-emitting device 110 and the feedback element 140 may be supported by (e.g., directly on) the wavelength conversion region 2630.

Some or all of the light not having the desired properties may be returned back (e.g., reflected back) by the feedback element. Some of the returned light may then be modified (e.g., by a manipulation region, such as a patterned and/or roughened surface, the wavelength conversion region) such that the light properties may be altered. Some of the altered light may once more impinge on the feedback element such that some or all of the light having the desired properties (e.g., polarization, propagation direction, and/or wavelength) may be emitted out of the system.

Since down-converted light has a lower energy (e.g., longer wavelength) than the bandgap energy of the light generation region (e.g., quantum wells of an active region), wavelength converted light that is returned back into the semiconductor stack may not be absorbed by the quantum wells.

As illustrated in the example system of FIG. 26, wavelength conversion region 2630 may be disposed in the path of light emitted by the light-emitting device 110. Wavelength conversion region 2630 may be disposed directly on the light-emitting device 110 (e.g., on the emission surface 138). Wavelength conversion region 2630 can include one or more phosphors and/or one or more quantum dots. Wavelength conversion region 2630 may convert (e.g., down-convert, up-convert) the wavelength of light impinging thereon.

Feedback element 140 may be arranged such that light leaving the system encounters feedback element 140 before exiting. Feedback element 140 may be disposed over wavelength conversion region 2630. For example, feedback element 140 may be disposed over or directly on wavelength conversion region 2630. Feedback element 140 may include one or more types of feedback elements, including one or more polarization feedback elements (e.g., reflective polarizers, such as wire-grid polarizers), one or more propagation direction feedback elements (e.g., such as reflective cavities with one or more apertures, one or more prisms, one or more prism arrays), and/or one or more wavelength filters (e.g., low-pass wavelength filters, high-pass wavelength filters, band-pass filters).

Light-emitting system 2600 can enable efficient light recycling, since at least some (a portion or substantially all) of the light 2611 emitted by light-generating region 120 having a first wavelength (represented by solid lines) may be down-converted by wavelength conversion region 2630 to light 2612 of a second wavelength (represented by dashed lines) corresponding to a lower energy. Light 2613 that is returned back into the system by feedback element 140 may thus be freely transmitted (e.g., represented by light rays 2613 and 2614) through light-emitting device 110 material stack without a chance of being absorbed by light-generating region 120 (e.g., active region) since down-converted light has a lower energy that the bandgap of the light-generating region and of material layers 122 and 124.

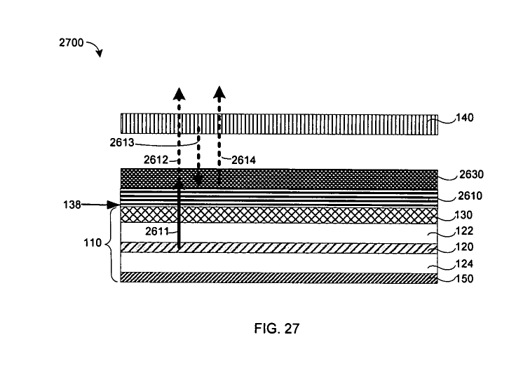

FIG. 27 is a cross-section of a light-emitting system 2700 that can include a wavelength conversion region 2630 and a wavelength filter 2610. Light-emitting system 2700 may be similar to light-emitting system 2600, except that a wavelength filter 2610 (e.g., a low-pass wavelength filter, a high-pass wavelength filter, a band-pass wavelength filter) may be configured so as to inhibit wavelength-converted (e.g., down-converted or up-converted) light from re-entering the light-emitting material stack. For example, wavelength filter 2610 may be disposed between emission surface 138 and wavelength converting material 2630.

As should be appreciated, since light recycling can be performed in connection with one or more characteristics of light, thus suitable features of embodiments presented herein in the context of light recycling for one characteristic may be used in connection with recycling of polarization, propagation direction, and/or wavelength.

As used herein, when a structure (e.g., layer, region) is referred to as being “on”, “over” “overlying” or “supported by” another structure, it can be directly on the structure, or an intervening structure (e.g., layer, region) also may be present. A structure that is “directly on” or “in contact with” another structure means that no intervening structure is present.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A light-emitting device comprising:
a light-emitting material stack including a light-generating region and a light emission surface; and
a polarizer configured to receive at least some light emitted from the light emission surface of the light-emitting material stack,
wherein the polarizer comprises first reflective regions at a first height and second reflective regions separated from the first metal regions and at a second height different from the first height.

2. The light-emitting device of claim 1, wherein the second reflective regions are offset laterally from the first reflective regions.

3. The light-emitting device of claim 1, wherein the second reflective regions are separated from the first reflective regions by less than 100 nm.

4. The light-emitting device of claim 1, further comprising a material region between the polarizer and the light emission surface of the light-emitting material stack.

5. The light-emitting device of claim 4, wherein the material region is electrically insulating.

6. The light-emitting device of claim 4, wherein the material region is electrically conductive.

7. The light-emitting device of claim 1, wherein the light emission surface of the light-emitting material stack comprises a dielectric function that varies spatially according to a pattern.

8. The light-emitting device of claim 7, wherein the pattern comprise a plurality of holes.

9. The light-emitting system of claim 8, wherein the plurality of holes have a size of less than 1 micron.

10. The light-emitting system of claim 7, wherein the pattern is non-periodic.

11. A light-emitting device comprising:
a light-emitting material stack including a light-generating region and a light emission surface;
a material region disposed over the light emission surface of the light-emitting material stack and comprising surface features having tapered cross-sections; and
a polarizer configured to receive at least some light emitted from the light emission surface of the light-emitting material stack, wherein the polarizer comprises reflective regions disposed over at least some of the surface features of the material region, wherein the reflective regions of two adjacent surface features are isolated from each other.

12. The light-emitting device of 11, wherein the surface features of the material region comprise a plurality of lines.

13. The light-emitting device of 12, wherein the plurality of lines are substantially parallel.

14. The light-emitting device of 11, wherein the surface features of the material region are separated by less than 75 nm.

15. The light-emitting device of 11, wherein the surface features of the material region have widths of less than 75 nm.

16. The light-emitting device of 11, wherein the material region comprises an electrically insulating material.

17. The light-emitting device of claim 11, wherein the light emission surface of the light-emitting material stack comprises a dielectric function that varies spatially according to a pattern.

18. A light-emitting device comprising:
an active region that generates light; and
a polarizer disposed relative to the active region such that a majority of the generated light has a first polarization.

19. The light-emitting device of claim 18, wherein the polarizer is disposed at least partially through the active region.

20. The light-emitting device of claim 18, further comprising a reflective layer disposed under the active region, and wherein the polarizer is disposed between the active region and the reflective layer.

21. The light-emitting device of claim 20, wherein the polarizer is disposed in contact with the reflective layer.

22. The light-emitting device of claim 18, further comprising a light emission surface, and wherein the polarizer is disposed over the light emission surface.

23. The light-emitting device of claim 22, wherein the light emission surface of the light-emitting material stack comprises a dielectric function that varies spatially according to a pattern.

24. The light-emitting device of claim 18, wherein the polarizer is within a distance of less than 100 nm from the active region.

25. The light-emitting device of claim 18, wherein the polarizer is within a distance of less than 50 nm from the active region.

26. The light-emitting device of claim 18, wherein the polarizer is within a distance of less than 25 nm from the active region.

27. The light-emitting device of claim 18, wherein at least 60% of the generated light has the first polarization.

28. The light-emitting device of claim 18, wherein at least 80% of the generated light has the second polarization.

29. The light-emitting device of claim 18, wherein the polarizer comprises a wire-grid polarizer.

30. A method of making a light-emitting device, the method comprising:
providing a light-emitting material stack including a light-generating region and a light emission surface; and
providing a polarizer configured to receive at least some light emitted from the light emission surface of the light-emitting material stack,
wherein the polarizer comprises first reflective regions at a first height and second reflective regions separated from the first metal regions and at a second height different from the first height.
